(19) United States
(12) Patent Application Publication
(10) Pub. No.: US 2026/0197968 A1
(43) Pub. Date: Jul. 9, 2026

(54) MULTI-CHIP JET IMPINGEMENT COOLING FOR HEAT DISSIPATION AND METHODS OF USE THEREOF

(71) Applicant: Purdue Research Foundation, West Lafayette, IN (US)

(72) Inventors: Ketan Yogi, West Lafayette, IN (US); Gopinath Sahu, West Lafayette, IN (US); Tiwei Wei, Lafayette, IN (US); Akshat Hetal Patel, West Lafayette, IN (US)

(21) Appl. No.: 19/431,226

(22) Filed: Dec. 23, 2025

Related U.S. Application Data
(60) Provisional application No. 63/741,772, filed on Jan. 3, 2025.

(51) Int. Cl. H05K 7/20; G06F 1/20

(52) U.S. Cl. CPC H05K 7/20272; G06F 1/20

(57) ABSTRACT

The invention generally relates to multi-chip jet impingement cooling for heat dissipation and methods of use thereof. In certain aspects, the invention provides a high performance computing (HPC) system comprising: a logic chip; a plurality of high bandwidth memory (HBM) chips; and a jet impingement cooling arrangement; wherein the HPC is arranged such that incoming fluid from the jet impingement cooling arrangement first impinges over the HBMs and is then redirected towards the logic chip to impinge again, thus cooling the HBMs and logic chip in series.

### RELATED APPLICATION

The present application claims the benefit of and priority to U.S. provisional patent application Ser. No. 63/741,772, filed Jan. 3, 2025, the content of which is incorporated by reference herein in its entirety.

### FIELD OF THE INVENTION

The invention generally relates to multi-chip jet impingement cooling for heat dissipation and methods of use thereof.

### BACKGROUND

The advent of 5G technology and Artificial Intelligence (AI) has driven the growth of semiconductor industry, particularly for high performance computing (HPC) packages. As the computational and memory requirements have increased drastically, more powerful chiplets such as logic chips are integrated with on-package memory such as High Bandwidth memories (HBMs), to adequately address the requirements of such data-intensive applications. Such an integration can be undertaken using 2.5D and 3D IC approach wherein, logic chip and HBMs are connected through an interposer which has embedded redistribution layers (RDLs) and through silicon vias (TSVs) for signal routing and power delivery This significantly reduces routing length, enabling faster data exchange and reduces latency.

Integrating different components onto the same interposer also influences the heat transfer among different chiplets. As different chiplets are placed on an interposer made from silicon and are connected through redistribution layers and microbumps made from copper, these key enablers of 2.5D and 3D integration also act as highly conductive thermal paths between different chiplets. This induces a thermal coupling or “crosstalk” between them. This can present a bottleneck on the overall performance of the package as different chiplets have different dissipation and temperature constraints. Thus, the chiplets which are more temperature sensitive may dictate the overall thermal design power (TDP) of the package. For HPCs, HBMs are the temperature sensitive components. Thus performance of the package may be limited by it, as the adjacent components such as logic chip, which performs the computations and in turn has higher power dissipation, may heat up the HBM through thermal coupling apart from the self-heating effects of the HBM. Thus, despite having very powerful logic chip, its full benefit may not be realised if HBMs on the package don't have adequate thermal management and hence both self-heating and thermal coupling becomes critical for the overall performance and TDP of such HPC 2.5D interposer packages.

A typical chip layout of a HPC package consists of a logic chip surrounded by multiple HBMs, all connected through a 2.5D silicon interposer substrate. AMD Radeon R9 Fury X, NVIDIA P100, AMD M1300, and NVIDIA Hopper H100 are excellent examples of such HPC packages with the former two having the typical layout of one central logic chip surrounded on opposite sides by 4 HBMs (two on each side). The latter two are recent examples of more advanced packages with multiple logic chip interacting with 6 or 8 HBMs on the same interposer.

An early approach for simultaneous thermal management of multiple chips was in the form of a thermal control module (TCM), which consisted of an air-cooled heat sink, also acting as the heat spreader and was used on the top of package lid. However, air cooling requires more space for larger heat sink to maintain the thermal performance as the TDP increases and thus doesn't scale well with TDP. A matured version of TCM was achieved by adding a liquid-cooled cold plate to the TCM. However, as the power and power densities of HPC packages are expected to rise in the coming years, such approaches are not adequate. Some of the advanced liquid cooling methods that have gained widespread attention are immersion cooling, microchannels & embedded cooling and jet impingement.

An immersion cooling strategy has been previously tried on a HPC (900 W TDP) package with one logic chip surrounded by 4 HBMs. A maximum junction temperature of 104.3° C. was achieved, which was further reduced to 97.9° C. by incorporating a vapour chamber with the package instead of a simple copper heat spreader. This enabled dissipation of nearly 200 W/cm² of power density at a thermal resistance of 0.0355° C./W. Others investigated the use of an oscillating heat pipe as a possible solution to mitigate localized hot spots in high power applications. The lowest thermal resistance they were able to achieve while managing hotspots of 4*4 mm² and 4×10 mm² was 0.0745 cm²·K/W for a hotspot flux up to 100 W/cm². Sill others investigated the use of an oscillating heat pipe as a heat spreader for a multi-chip module with 6 individual modules of 1 logic chip and 2 HBMs, all attached through a common substrate using flip chip boding. However, these approaches are implemented over the lid of the package which poses its own thermal resistance to the heat transfer. To further improve heat transfer, liquid cooling based direct on-chip solutions can be implemented as they eliminate the package lid and interact with the chip directly. Such cooling solutions can achieve remarkably high heat transfer rates and can scale well with the TDP of modern HPC packages.

Others have explored the feasibility of embedded microfluidic channels for HPCs by investigating its thermal performance with a single logic chip. They measured a maximum temperature of 55.9° C., corresponding to a thermal resistance of 0.27 cm²·K/W at a flow rate of 0.07 L/min.

Others have comprehensively explored the dual side cooling for HPC using embedded microchannels in the interposer and a cold plate. Fabricating the interposer in two halves to easily accommodate the microchannels, they were able to dissipate 672 W (168 W/cm²) from a 3-layer 3D stack of an accelerator, cache and microprocessor. A thermal resistance of 0.173 cm²·K/W was achieved at a flow rate of 0.5 L/min. Some have investigated a silicon based staggered embedded manifold integrated within a 18×20 mm² chip which mimics the logic die of a high powered HPC package. They experimentally achieved a thermal resistance of 0.108 cm²·K/W for a logic die power of 1200 W. Some have investigated direct liquid cooling of a similar package fabricated using Chip-on-Wafer-on-Substrate (CoWoS) technology. Using two inlets and single outlets, they were able to experimentally achieve a maximum TDP of 805 W with maximum junction temperature being 75° C. Their numerical model further predicted the TDP can be increased to 2 kW (at a flow rate of 8.64 L/min) by using micro pin fins over chip surfaces.

However, above cooling strategies have their own potential drawbacks. A common trend in embedded cooling, particularly for chiplets based on 3D integration, involves repurposing the TSVs as micro-pin fins to enhance heat transfer and creating microchannels around them. This may not be suitable for chiplets with high interconnection densities as the same physical space has to be distributed between TSVs and microchannels which may limit the maximum heat transfer possible. This may be avoided for 2.5D case by shifting the embedded microchannels into the interposer and avoiding competition for active space on the wafer. But this comes at the cost of moving away from the heat source.

Another aspect of embedded cooling is that the pressure drop associated with it rises rapidly as the chip size increases. Thus, for HPC packages which have a large footprint, embedded cooling network may have a large pressure drop associated with it.

Apart from the different cooling mechanisms described above, several other passive approaches have also been explored by researchers to reduce the thermal coupling in the HPC and improve the efficacy of the cooling schemes. Son et al. [21] embedded a through mold plate in the epoxy molding compound between the GPU and HBM of a low power package (290 W) with a forced air-cooled heat sink as an additional thermal path for the power dissipation of GPU. Strategic positioning of the mold plate reduced the HBM junction temperature by 10.3° C. and reduced the signal jitter by 4.54%. Some have combined horizontal through transmission lines with the embedded cooling channels for an HPC with inlet and outlet ports for the fluid network passing through GPU and HBMs respectively. The transmission lines were carefully incorporated in the DRAM layers of the 12-stack HBM and ran along the length of HBM. The transmission lines acted as additional heat transfer paths which improved temperature uniformity and overall heat dissipation to the working fluid. A 15.5% reduction was observed in the average DRAM layer when transmission lines were used along with embedded cooling and the overall thermal resistance was reported to be 0.211 K/W.

Another method of tackling the thermal coupling is to integrate an interposer made from a different material such as glass. Some have compared the impact of interposer material on the thermal performance of a logic die with a back-side power delivery network. They observed that utilizing a cooling scheme on the top of the logic die, the interposer material had a negligible effect on the logic die temperature while HBM temperature reduced by almost 10° C.

This is because lower thermal conductivity of glass reduced the thermal coupling between logic die and HBM. Integrating embedded cooling along with top cooling and glass interposer, the logic die temperature reduced by 14° C. while it had marginal effect HBM temperature.

However, such passive approaches may aid the cooling scheme but cannot serve as a standalone thermal management technique and hence there is a need for a comprehensive analysis of the actual layout of the package under appropriate cooling scheme.

### SUMMARY

The invention recognizes that microscale jet impingement cooling has excellent potential due to its high heat transfer rates, excellent scalability, and high coefficient of performance (COP). High-Performance computing (HPC) systems have multiple chips with dissimilar thermal dissipation and temperature constraints, integrated over a silicon interposer embedded with copper metal through silicon vias (TSVs), which makes its thermal management challenging. Temperature constraints of all chips are to be fulfilled simultaneously while also accounting for the complex thermal interactions among the chips through the interposer. In certain embodiments, the invention illustrates the performance of jet impingement cooling for a HPC system with a logic chip and four high bandwidth memory (HBM) chips, realized through copper blocks. The incoming fluid first impinges over the HBMs and is then redirected towards logic chip to impinge again, thus cooling the HBMs and Logic chip in series. The cooling strategy was able to achieve an unprecedented 1.86 kW of thermal design power subjected to maximum temperature constraint 105° C. and 85° C. for logic chip and HBMs, respectively. The minimum thermal resistance achieved was 0.183 cm²·K/W while managing a logic chip heat flux as high as 252 W/cm². The corresponding pressure drop was a modest 48.32 kPa for a net chip area of 1060 mm². Surface temperature measurement at various locations over logic chip (676 mm²) reveal that surface temperature uniformity is within 3° C. even at the highest TDP. Comparison of series and parallel design, using numerical model, reveals the former's superior thermal performance and the ability to support higher HPCs with TDPs, subjected to the aforementioned temperature constraints.

In certain aspects, the invention provides, a high performance computing (HPC) systems including a logic chip, a plurality of high bandwidth memory (HBM) chips, and a jet impingement cooling arrangement, wherein the HPC is arranged such that incoming fluid from the jet impingement cooling arrangement first impinges over the HBMs and is then redirected towards the logic chip to impinge again, thus cooling the HBMs and logic chip in series.

In other aspects, the invention provides, methods for cooling a high performance computing (HPC) system involving providing an HPC having a logic chip, a plurality of high bandwidth memory (HBM) chips; and a jet impingement cooling arrangement, and providing, via the jet impingement cooling arrangement, a flow of fluid to the HPC, wherein the HPC is arranged such that the incoming fluid from the jet impingement cooling arrangement first impinges over the HBMs and is then redirected towards the logic chip to impinge again, thus cooling the HBMs and logic chip in series.

In certain embodiments of the systems and methods herein, the jet impingement cooling arrangement had distributed inlet nozzles and outlet nozzles. In certain embodiments of the systems and methods herein, each inlet nozzle is surrounded by four outlet nozzles and vice-verse, except for the outermost master outlet nozzles. In certain embodiments of the systems and methods herein, each HBM chip had an inlet nozzle array of 3×5 at a pitch of 2 mm. In certain embodiments of the systems and methods herein, the logic chip had an inlet nozzle array of 12×12 at a pitch of 2 mm.

In certain embodiments of the systems and methods herein, the jet impingement cooling arrangement has a total of 204 inlet nozzles spread over a total chip area of 1060 mm². In certain embodiments of the systems and methods herein, each inlet and outlet nozzle has a diameter of 500 micrometers.

In certain embodiments of the systems and methods herein, the jet impingement cooling arrangement comprises two master inlet nozzles that split the overall flow rates into two inlet streams, and one common master outlet nozzle for both inlet streams. In certain embodiments of the systems and methods herein, the jet impingement cooling arrangement further comprises pressure tappings, which provide fluid pathways from inlet nozzles and outlet nozzles. In certain embodiments of the systems and methods herein, the fluid pathways are connected across a pressure transducer through tub and the overall pressure drop is measured, wherein thermocouple holes are also provided in the jet impingement cooling arrangement to measure temperature of the fluid after the fluid has impinged over the HBMs.

### BRIEF DESCRIPTION OF THE DRAWINGS

FIGS. 1A-B show a microscale jet impingement cooling of a 2.5D Interposer package for (A) Parallel cooling arrangement (PRIOR ART), (B) Series cooling arrangement.

FIG. 2 panel A shows a subassembly of heater blocks in 3-plate enclosure to mimic a 2.5 D interposer package for HPC systems, panel B shows a heater block to mimic logic chip, panel C shows a heater blocks to mimic HBMs, panel D shows a cut section of the assembly to highlight its internal features, and panel E shows AN actual chip layout for an HPC package.

FIG. 3 panel A shows a microscale jet impingement cooler based on series arrangement and its different features, panel B shows an internal fluid domain of series cooler, panel C shows an internal fluid domain for an equivalent parallel cooler, panel D shows a cut section of the internal fluid domain of series cooler, and panel E shows a magnified view of cut section of internal fluid domain of series cooler highlighting the fluid flow inside the cooler.

FIG. 4 panel A shows a logic chip heater block in bottom plate, panel B shows a HBM heater blocks in middle plate, panel C shows a placement of top plate to arrange in the desired chip layout, panel D shows a subassembly of heater block enclosure with gasket, panel E shows a nozzle array of the fabricated microscale jet impingement cooler, panel F shows a various tubings of the microscale jet impingement cooler

FIG. 5 panel A shows an overall assembly of heater-enclosure subassembly and microscale jet impingement cooler along with thermocouple, panel B shows a cut section of the cooler, panel C shows a magnified view of the cut section highlighting the placement of thermocouples, panel D shows a top view of the assembly, and panel E shows a magnified view of the assembly to highlight the location of thermocouple ports.

FIG. 6 panel A shows a heater-enclosure subassembly with heater thermocouples attached, panel B shows a sensor map schematic plotted over the chip layout, panel C shows a subassembly with logic chip thermocouples attached, and panel D shows a subassembly with HBM thermocouples attached (thermocouples for only HBM-3 are shown for illustration).

FIG. 7 panel A shows a schematic diagram of the flow loop, panel B shows a flow loop used for experimental characterization, and panel C shows a test section

FIG. 8 panel A shows an overall mesh used for numerical study of half the cooler, panel B shows a magnified view of mesh elements for HBMs, panel C shows a magnified view of mesh elements for logic chip, panel D shows a magnified view of mesh elements and inflation layers at 100 um size, panel E shows a magnified view of mesh elements and inflation layers at 75 um size, and panel F shows a magnified view of mesh elements and inflation layers at 50 um size. Mesh statistics are also tabulated with the mean and standard deviation values of element quality, orthogonality and skewness.

FIG. 9 panels A-B show a comparison of experimental and simulation results for (panel A) average chip surface temperature of logic chip and all HBMs and (panel B) cooler pressure drop.

FIG. 10 panels A-C show effect of logic chip flux on (panel A) average logic chip surface temperature (panel B) average chip surface temperature for HBM-1 & 3 (panel C) average chip surface temperature for HBM-2 & 4 for P_{HBM}=40 W at different cooler flow rates. The maximum logic chip heat fluxes for different flow rates is also highlighted, obtained through extrapolation of experimental data for T_{L,max}=105° C.

FIG. 11 panels A-C show effect of flow rate on thermal resistance for (panel A) logic chip (panel B) HBM 1 & 3 (panel C) HBM 2 & 4 for different values of logic chip power at P_{HBM}=40 W.

FIG. 12 shows numerical results of exit axial velocity profile through inlet nozzles of HBM 1 and 2 at different HBM flow rates. The relative distribution of flow rate is shown along with the trendline of velocity front.

FIG. 13 panels A-B show effect of cooler flow rate on (panel A) cooler pressure drop (panel B) COP for different logic chip power at P_{HBM}=40 W.

FIG. 14 panels A-D show contours of non-dimensional surface temperature (numerical results) for (panel A) P_{L}=750 W, P_{HBM}=40 W, Q⋅_{flow}=1 L/min (TDP=1.16 kW) (panel B) P_{L}=750 W, P_{HBM}=40 W, Q⋅_{flow}=4 L/min (TDP=1.16 kW) (panel C) P_{L}=500 W, P_{HBM}=40 W, Q⋅_{flow}=4 L/min (TDP=660 W) (panel D) P_{L}=1700 W, P_{HBM}=40 W, Q⋅_{flow}=4 L/min (TDP=1.86 kW). The surface temperature evaluated from experimental measurements are mentioned in white font at their respective locations on the package. The maximum and minimum temperature of each chip is shown as ordered pairs (Tmin, Tmax) on the side of chips.

FIG. 15 panels A-C show comparison of numerical results for series and parallel configuration in terms of (panel A) average chip surface temperature (panel B) Overall cooler pressure drop (panel C) Exit axial velocity profile through logic chip inlet nozzles at different cooler flow rates. The trendline of the maximum velocity is also shown with dotted lines.

FIG. 16 panel A shows a schematic of the cooler showing the various plot lines (panel B) temperature variation along plot line Z on logic chip surface for series and parallel coolers at Q⋅_{flow}=2 & 4 L/min (panel C) Temperature variation of chip surfaces along plot lines X₁, X₂ and X₃ for series and parallel coolers at Q⋅_{flow}=2 L/min (panel D) temperature variation of chip surfaces along line X1, X2 and X3 for series and parallel coolers at Q⋅_{flow}=4 L/min. Trendlines are also shown for plot lines Z and X₂ using double dot-dash lines.

FIG. 17 panels A-B show effect of mesh size on (panel A) Average chip surface temperature (panel B) cooler pressure drop at Q⋅_{flow}=1 and 4 L/min.

FIG. 18 panels A-F show comparison of series and parallel cooler at P_{L}=1000 W, P_{HBM}=40 W, Q⋅_{flow}=2 L/min: (panel A) Schematic of series cooler (panel B) Schematic of parallel cooler (panel C) contour plot of velocity over plane A-A′ of series cooler (panel D) contour plot of velocity over plane A-A′ of parallel cooler (panel E) contour plot of nondimensional temperature over chip surface for series cooler (panel F) contour plot of non-dimensional temperature over chip surface for parallel cooler.

FIG. 19 panels A-F show comparison of series and parallel cooler at P_{L}=1000 W, P_{HBM}=40 W, Q⋅_{flow}=4 L/min: (panel A) Schematic of series cooler (panel B) schematic of parallel cooler (panel C) contour plot of velocity over plane A-A′ of series cooler (panel D) contour plot of velocity over plane A-A′ of parallel cooler (panel E) contour plot of non-dimensional temperature over chip surface for series cooler (panel F) contour plot of non-dimensional temperature over chip surface for parallel cooler.

FIG. 20 panels A-F show comparison and parallel cooler at P_{L}=1700 W, P_{HBM}=40 W, Q⋅_{flow}=4 L/min: (panel A) schematic of series cooler (panel B) schematic of parallel cooler (panel C) contour plot of velocity over plane A-A′ of series cooler (panel D) contour plot of velocity over plane A-A′ of parallel cooler (panel E) contour plot of nondimensional temperature over chip surface for series cooler (panel F) contour plot of non-dimensional temperature over chip surface for parallel cooler.

### DETAILED DESCRIPTION

The invention generally relates to multi-chip jet impingement cooling for heat dissipation and methods of use thereof. The die-to-die thermal coupling between two identical 8×8 mm² dies integrated onto a 10×20 mm² interposer under natural convection has been numerically investigated. Glass and silicon with anisotropic thermal conductivities were considered as the interposer materials. A comprehensive study focusing on effect of interposer thickness and thermal conductivity anisotropy revealed stronger thermal coupling effects in silicon than glass which increases with an increase in the interposer.

The thermal coupling with a 3D printed microscale jet impingement cooler for lidded and lidless configurations has also been investigated. While operating only one of the chips at 50 W and measuring the temperature in both chips, it has been observed that the inactive chip temperature increased by 1.5° C. at 0.2 L/min flow rate which reduced to <0.1° C. as flow rate was increased beyond 0.4 L/min. The active chip temperature reduced from 107° C. to 53° C. This highlights the excellent capability of microscale jet impingement cooling in reducing the thermal coupling in multi-chip modules.

The heat conduction equation for a 2.5D interposer package with a logic chip and eight HBMs to investigate the thermal gradients throughout the package has been numerically solved. A key observation is that beyond a certain cooler flow rate value, HBM temperature limit was more likely to be voided first, while at smaller flow rates, logic chip temperature limit became more critical.

The above illustrate the thermal performance of various solutions under a single chip configuration with aim to upgrade TDP of HPC systems or relied on numerical models for multi-chip packages. However, experimental studies investigating the actual multichip layout with logic chips and HBMs have been extremely scarce.

In certain aspects, the invention herein generally provides a microscale jet impingement cooling for an actual HPC package layout with one logic chip surrounded by 4 HBMs on opposite sides. This inventive approach implements microscale jet impingement cooling to upgrade the TDP of an HPC beyond 1 kW using a multichip setup for a maximum logic chip temperature of T_{L,max}=105° C. and maximum HBM temperature of T_{HBM,max}=85° C. In an illustrative embodiment, the multi-chip setup includes five heater blocks made from oxygen free copper, which then used to realize the HPC package. A 3-piece enclosure, made from rigid 10K resin, is used to assemble all heater blocks in this configuration.

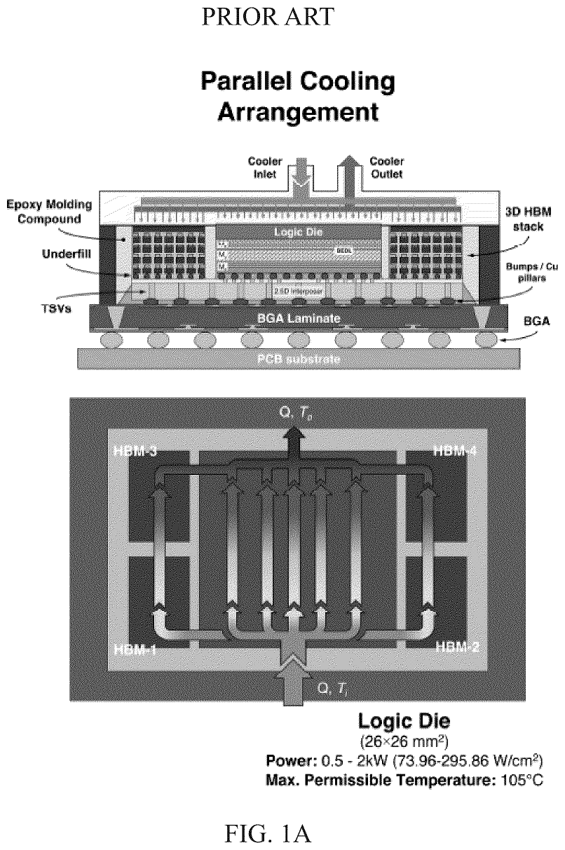

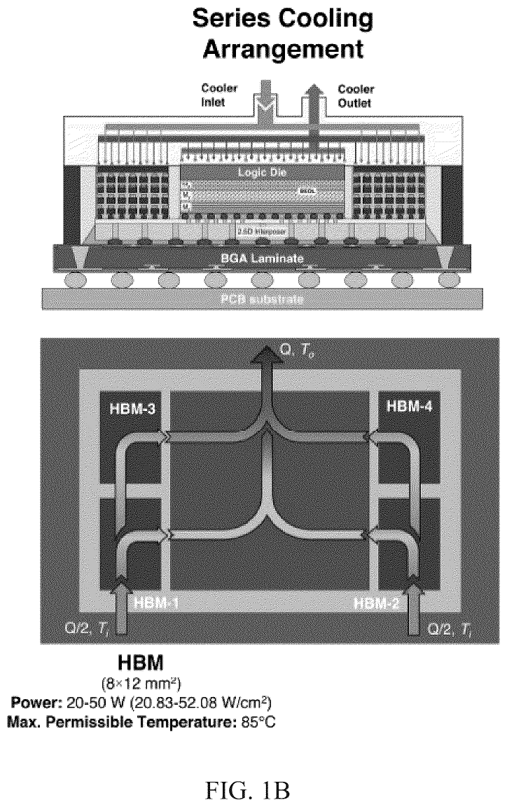

A typical prior art cooler design is based on parallel cooling arrangement as shown in FIG. 1A, where the overall flow rate gets distributed amongst different chips. Instead, a microscale jet impingement cooler based on series arrangement, as shown in FIG. 1B, is designed with inlet/outlet nozzles for all 5 chips integrated into the same cooler. Such series flow arrangement enables accommodating the entire flow for the logic chip which enhances the heat transfer over logic chip surface. The incoming fluid first impinges over the surface of 4 HBMs and is then transported to the centre to impinge over the logic chip. Furthermore, such series flow configuration takes advantages of the minimal temperature rise of the working fluid due to the high liquid flow rate, allowing the series connection of multiple coolers. Temperature and pressure drop measurements were extracted experimentally to investigate the performance of the proposed cooler and to characterize it in terms of thermal resistance for each chip. A numerical model is solved to understand the flow inside the cooler and jet impingement over the chips to understand the subtleties of the cooler's performance.

### Heater Block Arrangement

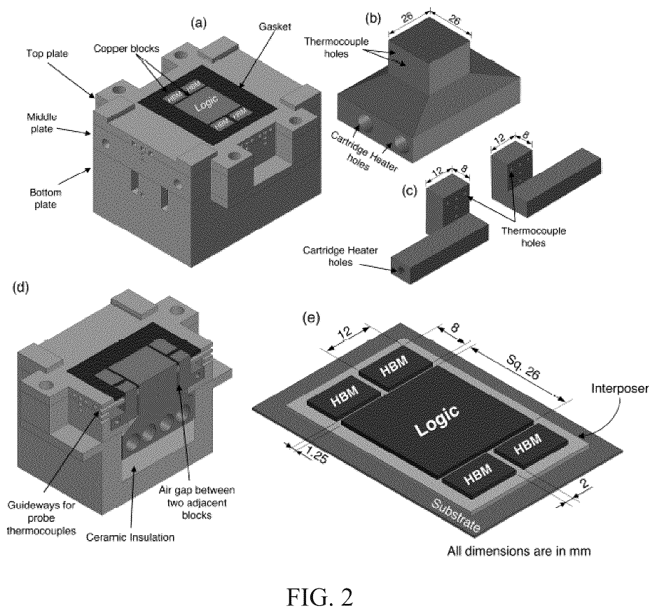

To investigate a HPC system, a typical chip layout, adapted from NVIDIA P100, is considered with one central logic chip surrounded by 4 HBM chips, two on opposite sides. A key objective of the present study is to investigate the performance of proposed cooling solution for a HPC package with a TDP beyond 1 kW. Thus, a special heater setup is designed from heater blocks, made from oxygen free copper, which mimics the steady state thermal dissipation of actual chips to ensure reliable performance even at very high heat fluxes. A 3-plate enclosure is designed and fabricated from Rigid 10K resin to assemble heater blocks in the desired chip layout and minimize thermal interaction among different heater blocks. Heater blocks for logic chip and HBMs is shown in FIG. 2 panel B and FIG. 2 panel C respectively. FIG. 2 panel A shows the heater blocks enclosure subassembly. Four cartridge heaters of ⅜th inch diameter, each with 500 W capacity, are inserted in the cylindrical holes of logic chip heater block using Boron Nitride thermal paste (from Slice engineering) which has a thermal conductivity of 31.4 W/m·K at 100° C. Similarly, one cartridge of ⅛th inch diameter, each with 50 W capacity, is inserted into each HBM heater block. The maximum TDP of the heater arrangement is 2.2 kW with maximum logic chip and HBM heat fluxes being 295.86 W/cm2 and 52.08 W/cm2 respectively. FIG. 2 panel D depicts the cut section of subassembly and reveals the ceramic insulation block used FIGS. 1A-B Microscale jet impingement cooling of a 2.5D Interposer package for (FIG. 1A, PRIOR ART) Parallel cooling arrangement (FIG. 1B) Series cooling arrangement at the bottom of logic chip block to minimize heat loss to enclosure. Lastly, FIG. 2 panel E shows the chip layout for an actual HPC which has been realized using the heater-enclosure subassembly.

### Cooler Design

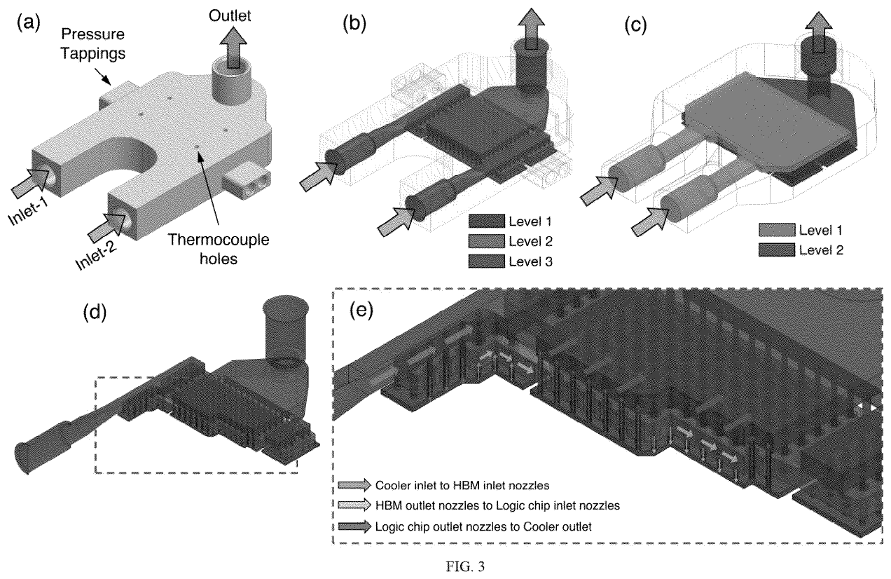

A series cooling arrangement is adapted to implement microscale jet impingement cooling of the HPC heater arrangement described herein. The designed cooler, shown in FIG. 3 panel A, was fabricated from Ceramic like high temperature resin (PerFORM) using stereolithography. The entire jet impingement arrangement had distributed inlets and outlets, where each inlet nozzle is surrounded by four outlet nozzles and vice-verse (except for the outermost outlet nozzles). Each HBM chip had an inlet nozzle array of 3×5 at a pitch of 2 mm while the logic chip had an inlet nozzle array of 12×12 at a pitch of 2 mm. The cooler has a total of 204 inlet nozzles spread over a total chip area of 1060 mm². Each nozzle has a diameter of 500 μm. The cooler has two inlets, which splits the overall flow rates into two streams, and one common outlet for both streams. The cooler has pressure tappings, which provide fluid pathways from inlet and outlet of the cooler. These fluid pathways are connected across a pressure transducer through tub and the overall cooler pressure drop is measured. Thermocouple holes are also provided in the cooler to measure the temperature of fluid stream after they have impinged over the HBMs. FIG. 3 panel B shows the internal fluid domain of the series cooler divided into 3 levels, the top level (level 1) highlighted in purple, the intermediate level (level 2) highlighted in violet and bottom level (level 3) highlighted in navy blue. FIG. 3 panel C shows the internal fluid domain for an equivalent parallel cooler divided into 2 levels, the top (level 1) highlighted in (lilac), and the bottom level (level 2) highlighted in navy blue.

FIG. 3 panel D shows a cut section of the internal fluid domain for series cooler, shown in FIG. 3 panel B, while FIG. 3 panel E shows the magnified view highlighting the fluid flow through the different levels of the cooler. The fluid streams enter the cooler through the two lateral inlets at level 1 and encounter the inlet nozzles for the HBMs. Through these inlets, the working fluid first impinges over the four HBMs at level 3, as shown by the blue arrows in FIG. 3 panel E. The fluid, after impinging over the HBMs, exit the impingement cavity through the HBM outlet nozzles as shown by the orange arrows in FIG. 3 panel E. The fluid then flows towards the centre of the cooler in level 2 and encountering the inlet nozzles for logic chip. The fluid then impinges over the logic chip, shown by orange arrows, and exits the impingement cavity through the outlet nozzles as shown by the red arrows. Eventually the fluid flows laterally towards the cooler outlet and exits the cooler. As compared to the series cooler with three levels, the parallel cooler only has two levels where the fluid enters through the two inlets and gets distributed simultaneously amongst the inlet nozzles of all five chips. The fluid then impinges over the chips only once and exits the cooler. For series arrangement, rerouting of the fluid stream that has already impinged over the HBMs towards the logic chip enables the entire fluid flow to impinge over the logic chip, a feature absent in parallel arrangement where only a portion of the incoming fluid stream impinges over the logic chip.

Overall Enclosure-Cooler Assembly. Sensor Map. And Flow Loop

This section first describes the subassembly of heater block-enclosure and then describes the assembly of microscale jet impingement cooler with the subassembly. Lastly, it describes the flow loop used for experiments and the sensor layout for the different chips for temperature measurements.

### Heater Block-Enclosure Sub-Assembly

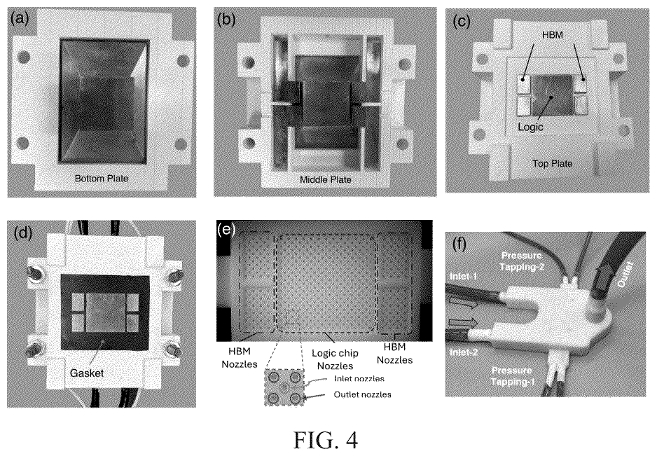

The bottom plate houses the heater block for logic chip, as shown in FIG. 4 panel A. Similarly, the middle plate houses the heater block for HBMs as shown in FIG. 4 panel B. The top plate is designed to match the chip layout and ensures that the heater blocks arranged in the desired layout as shown in FIG. 4 panel C. The full subassembly of heater block and enclosure is shown in FIG. 4 panel D. The top plate's thickness is minimized such that the lateral cross-sectional area for heat transfer between chips is minimum and the plate still maintains its structural integrity. Further the heater blocks for logic chip and the HBMs are separated by an air gap (except at the top plate) which acts an insulating layer. The top plate also contains protrusions which aid in aligning the microscale jet impingement cooler with the heater blocks. Finally, the top plate also has chamfer along the periphery of all rectangular FIG. 4 panel A Logic chip heater block in bottom plate FIG. 4 panel B HBM heater blocks in middle plate FIG. 4 panel C Placement of top plate to arrange in the desired chip layout FIG. 4 panel D Subassembly of heater blockenclosure with gasket FIG. 4 panel E Nozzle array of the fabricated microscale jet impingement cooler FIG. 4 panel F Various tubings of the microscale jet impingement cooler holes for chips. This chamfer provides space between heater blocks and top plate which can is filled with epoxy (DP420 from 3M Scotch), providing a leak proof joint. All enclosure plates have slots for thermocouple probes which act as guideways and support their weight. Further, the bottom and middle plate also contains spaces to extract wiring of the cartridge heaters as shown in FIG. 4 panel D.

FIG. 4 panel E shows the bottom view of the fabricated microscale jet impingement cooler highlighting the nozzle arrays for all the chips. FIG. 4 panel F shows the fabricated microscale jet impingement cooler with the different inlets, outlets and pressure tapings.

Assembly of Cooler with Heater Block-Enclosure Subassembly

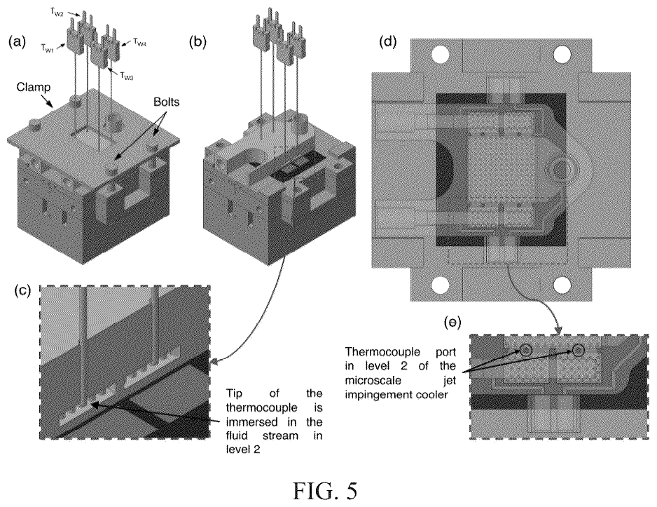

FIG. 5 panel A shows the overall assembly of the microscale jet impingement cooler over the heaterenclosure subassembly using a clamp plate and four bolts. The clamp is tightened such that fluid leakage is prevented at the maximum flow rate considered for the present study. FIG. 5 panel A also shows the thermocouples (TW1-TW4) attached inside the cooler to measure the temperature of the fluid stream in level 2. This measurement enables investigating the temperature rise of the fluid when it flows towards logic chip inlet nozzle array after it has impinged over the HBMs. FIG. 5 panel B shows the cut section of the cooler while FIG. 5 panel C shows the magnified view of the cut section. The thermocouples are attached with the cooler such that their tip is just immersed into the fluid volume and accurate temperature measurements can be taken while the fluid flow perturbation by the thermocouple tip is minimized. FIG. 5 panel D shows the top view of the assembly without the clamp to highlight how the cooler nozzle array is superimposed over the chip layout. FIG. 5 panel E shows its magnified view to highlight the placement of thermocouple ports with respect to the chip layout.

### Sensor Map

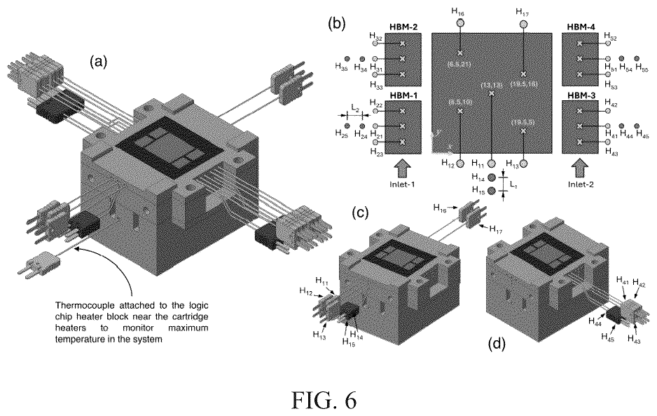

A total of 28 thermocouple probes (K-type KMQSS-IM100U-100 from OMEGA) are used for the heater-enclosure subassembly to measure the surface temperature and the flux within each individual chips. FIG. 6 panel A shows the heater-enclosure subassembly with all 28 thermocouples attached to the heater blocks using Boron Nitride thermal paste to minimize contact resistance. Out of 28 thermocouples, one is attached at the bottom of the logic chip heater block to monitor the maximum temperature in the system which is expected to occur between the holes for cartridge heaters. The maximum temperature in the system is restricted to 300° C. to minimize the rapid oxidization of the oxygen free copper blocks which can lead to rapid reduction in its thermal conductivity which can lead to further increase in maximum temperature in the system. This also restricts the thermal expansion of heater block within manageable limits such that no cracks are developed in the enclosure and leakage is minimized. FIG. 6 panel B shows the overall sensor map for all five chips. The thermocouples are distributed into two groups and are colour coded accordingly.

The first group is for the thermocouples shown by green dots which are attached vertically above each other at a distance of L₁=0.4 cm (for logic chip) or L₂=0.35 cm (for HBMs). The measurements from these thermocouples are used to evaluate the heat flux through logic chip and each HBM using equations (1) & (2) respectively, which are as shown below:

$$Logic chip : {q}_{L}^{″} = \frac{{k}_{Cu} ( {T}_{H 11} - {T}_{H 14} )}{{L}_{1}} = \frac{{k}_{Cu} ( {T}_{H 14} - {T}_{H 15} )}{{L}_{1}} \qquad ( 1 )$$

$$HBMs : {q}_{HBM - 3}^{″} = \frac{{k}_{Cu} ( {T}_{H 41} - {T}_{H 44} )}{{L}_{2}} = \frac{{k}_{Cu} ( {T}_{H 44} - {T}_{H 45} )}{{L}_{2}} \qquad ( 2 )$$

Where, q″_{I} (W/m²) is the heat flux through i^{th} block, k_{Cu} (W/m·K) is the thermal conductivity of oxygen free copper and has a value of 390 W/m·K, T_{Hi} (° C.) is the temperature reading of ith thermocouple. The second category are the thermocouples shown by yellow dots which attached in the same horizontal plane. The measurements from these thermocouples are used along with heat flux values for each individual chip to evaluate the surface temperature at that location using equation (3) which as shown below:

$${T}_{S , i} = {T}_{H , i} - \frac{{q}_{i}^{″} \times {L}_{i}}{{k}_{Cu}} \qquad ( 3 )$$

Where T_{S,i} (° C.) is the surface temperature above ith thermocouple. Using the surface temperature and heat flux values, thermal resistance for each individual chip can be evaluated using equation (4) and (5) as below:

$${R}_{th} = \frac{{\overline{T}}_{S , i} - {T}_{IN}}{{q}_{i}^{″}} \qquad ( 4 )$$

$$( 5 )$$

$${T}_{IN} = \{ \begin{matrix}\frac{{\sum }_{i = 1}^{4} {T}_{Wi}}{4} & for Logic Chip \\ 20 ° C . & for HBMs\end{matrix} ; {\overline{T}}_{S , i} = \frac{{\sum }_{i = 1}^{N} {T}_{S , i}}{N} ; N = \{ \begin{matrix}5 & for Logic Chip \\ 3 & for HBMs\end{matrix}$$

Where Rₜₕ (cm₂·K/W) is thermal resistance of the chip and T_{IN} (° C.) is the inlet fluid temperature of working fluid kept constant at 20° C. for HBMs and it is the average of the temperature readings from thermocouples T_{W1}-T_{W4} for logic chip. The corresponding heat transfer coefficient, h̅ (W/m²·K) is evaluated using equation (6) which is as shown below:

$$\overline{h} = \frac{1}{{R}_{th}} = \frac{{q}_{i}^{″}}{{\overline{T}}_{S , i} - {T}_{IN}} \qquad ( 6 )$$

FIG. 6 panel C shows the thermocouples for logic heater block only and similarly FIG. 6(b) shows the thermocouples for HBM-3 only. Both the figures can be used to correlate the physical location of thermocouples in the subassembly with the sensor map schematic shown in FIG. 6 (b). Similarly, physical locations of thermocouples for remaining HBMs can be correlated with the sensor map schematic shown in FIG. 6 panel B. Lastly, non-dimensional temperature, θ*, is defined to compare the surface temperature non-uniformities later in the study. It is defined as shown below:

$${θ}^{*} = \frac{T - {T}_{min}}{{T}_{max} - {T}_{min}} \qquad ( 7 )$$

### Flow Loop

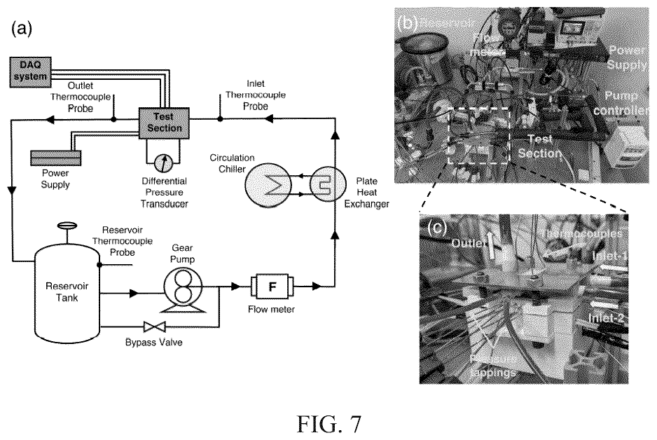

FIG. 7 panel A shows the schematic diagram of flow used for the present study. Deionized (DI) water is used as the working fluid for the present study. The reservoir tank is filled with DI water and a thermocouple probe is immersed into the reservoir fluid to measure its temperature. The tank is connected to a Mag-Drive gear pump (GC-M35.JF5S.E from Micropump) which generates the required flow rate in the flow loop. The pump is controlled by a variable frequency drive, SM2 Vector 1 HP VFD from LEESON speedmaster. A Coriolis flow meter (CODA K-series from Alicat Scientific) is used upstream of the test section to measure the flow rate of DI water in the loop. The inlet temperature of DI water is maintained at 20° C. using a liquid-to-liquid plate heat exchanger before it enters the test section. Two thermocouples (T-type TMQ316SS-125G-6 from OMEGA) are used to measure the temperature of the incoming and outgoing fluid stream across the test section. The four cartridge heaters of logic chip heater block are powered using two DC powers supplies (XLN15010-GL from BK Precision) while the four cartridge heaters for all HBMs are powered using a single DC power supply (SPS-12003 from Jesverty). As the maximum temperature in the system is to be limited to 300° C., the maximum Total Design Power (TDP) of the package for a given flow rate is limited according to this practical consideration apart from the operating constraints of maximum logic and HEM temperature.

Pressure tappings from the microscale jet impingement cooler are connected across a differential pressure transducer (PX409-100DWU5V from OMEGA) to measure the pressure drop across the inlet and outlet of the microscale jet impingement cooler. Using the pressure drop and flow rate measurements, the pump power and the coefficient of performance (COP) can be evaluated using equation respectively, which are as shown below:

$${W}_{P} = {\dot{Q}}_{flow} \times Δ P \qquad ( 8 )$$

$$COP = \frac{TDP}{{W}_{P}} = \frac{{P}_{L} + 4 {P}_{HBM}}{{W}_{P}} = \frac{{q}_{L}^{″} {A}_{L}^{2} + 4 {q}_{HBM}^{″} {A}_{HBM}^{2}}{{W}_{P}} \qquad ( 9 )$$

Where Wₚ is the pump power, Q_{flow} (L/min) is the cooler flow rate and ΔP (Pa) is the pressure drop measure by the differential pressure transducer. A_{L} (m²) and A_{HBM} (m²) were the chip area of logic chip and HBMs. Data acquisition is done using DAQ970A system from Keysight technologies with two DAQM901A modules which can house a total of 40 thermocouples. BenchVue software from Keysight technologies is used to save and export data recorded during experiments. The uncertainties in different instruments and parameters calculated from the measurements is as listed in Table I.

TABLE I
List of uncertainties in the measurements
from different instruments and parameters

| Parameter (Instrument) | Symbol (units) | Accuracy |
|---|---|---|
| Flow rate | \dot{Q}_{flow} (m³/s) | ±0.2% |
| (Coriolis flow meter | | |
| from Alicat scientific) | | |
| T-type thermocouple | T (° C.) | 0.75% |
| (TMQ316SS-125G-6 | | (0-315° C.) |
| from OMEGA) | | |
| K-type thermocouple | | 0.75% |
| (KMQSS-IM100U-100 | | (0-700° C.) |
| from OMEGA) | | |
| Pressure difference | ΔP (Pa) | ±0.8% |
| (PX409-100DWU5V | | (0.01-2 bar) |
| from OMEGA) | | |
| Heat flux | q [symbol] (W/cm²) | ±5.13% |
| Thermal resistance | R [symbol] (cm² · K/W) | ±5.64% |
| Heat transfer coefficient | h̅ (W/m² · K) | ±5.64% |

[symbol]

indicates data missing or illegible when filed

### Numerical Model

Apart from the experimental results, a numerical model is also solved, and its results are also discussed to improve the understanding of the flow field characteristics inside the microscale jet impingement and its effect on the surface temperature variation of the different chips. To simplify the numerical model and reduce the computational time, the following assumptions are undertaken:
1. Steady state conditions prevail.
2. The thermophysical properties of the fluid (DI water) are temperature independent and remain constant.
3. Only half of the fluid domain is modelled while symmetry boundary condition accounts for the rest.
4. Effect of jet impingement cooler material is neglected and hence only the fluid domain is modelled.
5. Heat flux extracted from experiments are used for each individual chips and can account for conduction amongst different heater blocks (through thermal coupling) within the heater block-enclosure subassembly. Hence, heater block-enclosure is not explicitly modelled.
6. Viscous dissipation is neglected.
   The fluid flow inside the microscale jet impingement cooler is governed by the following governing equations:
Continuity equation:

$$\frac{\partial }{\partial {x}_{i}} ( {u}_{i} ) = 0 \qquad ( 10 )$$

Momentum equations:

$$\frac{\partial }{\partial {x}_{j}} ( {u}_{i} {u}_{j} ) = - \frac{\partial }{\partial {x}_{i}} ( \frac{p}{ρ} + \frac{2}{3} {K}_{t} ) + \frac{\partial }{\partial {x}_{j}} [ ( v + {v}_{t} ) ( \frac{\partial {u}_{i}}{\partial {x}_{j}} + \frac{\partial {u}_{j}}{\partial {x}_{i}} ) ] \qquad ( 11 )$$

Energy Equations:

$${u}_{i} \frac{\partial T}{\partial {x}_{i}} = \frac{\partial }{\partial {x}_{i}} [ ( α + {α}_{t} ) \frac{\partial T}{\partial {x}_{i}} ] \qquad ( 12 )$$

The above equations contain three unknown components arising from Reynolds averaging the Navier-Stokes and energy equations: Kₜ (m²/s²) turbulent kinetic energy, νₜ (m²/s) which is the eddy viscosity and αₜ (m²/s) which is the turbulent thermal diffusivity. Thus, to obtain these parameters and achieve closure of the system of governing equations, turbulence model equations are also solved along with equations (10)-(12). Transition Shear Stress Transport (SST) model along with γ-Re_{θt} Revs transition model is selected as the turbulence model for the present study because of its excellent accuracy in predicting heat transfer for jet impingement applications and the transition to turbulence in the wall boundary layer zone. Transition SST is a four-equation model that solves for the specific dissipation rate, ω (s⁻¹) and turbulent kinetic energy which, along with other expressions such as that of turbulent Prandtl number (Prₜ), can be go used to evaluate the required unknowns. Apart from solving for ω and Kₜ, the model also solves for intermittency, γ, and transition momentum thickness Reynolds number, Re_{θt}, which can capture the thermo-hydraulic characteristics in the transition regime. The additional transport equations solved for transition SST turbulence model are listed here as shown below:

### Transport Equation for Turbulent Kinetic Energy:

$$\frac{\partial }{\partial {x}_{i}} ( ρ {K}_{t} {u}_{i} ) = \frac{\partial }{\partial {x}_{i}} [ ( μ + \frac{{μ}_{t}}{{σ}_{k}} ) \frac{\partial k}{\partial {x}_{i}} ] + {G}_{k} - {Y}_{k} + {S}_{k} \qquad ( 13 )$$

### Transport Equation for Specific Dissipation Rate:

$$\frac{\partial }{\partial {x}_{i}} ( ρω {u}_{i} ) = \frac{\partial }{\partial {x}_{i}} [ ( μ + \frac{{μ}_{t}}{{σ}_{ω}} ) \frac{\partial ω}{\partial {x}_{i}} ] + {G}_{ω} - {Y}_{ω} + {S}_{ω} \qquad ( 14 )$$

### Transport Equation Intermittency:

$$\frac{\partial }{\partial {x}_{i}} ( ργ {u}_{i} ) = \frac{\partial }{\partial {x}_{i}} [ ( μ + \frac{{μ}_{t}}{{σ}_{γ}} ) \frac{\partial γ}{\partial {x}_{i}} ] + {G}_{γ} - {Y}_{γ} \qquad ( 15 )$$

### Transport Equation for Transition Momentum Thickness Reynolds Number:

$$\frac{\partial }{\partial {x}_{i}} ( ρ \text{?} {u}_{i} ) = \frac{\partial }{\partial {x}_{i}} [ \text{?} ( u + {u}_{t} ) \frac{\partial \text{?}}{\partial {x}_{i}} ] + {S}_{{θ}_{t}} \qquad ( 16 )$$

$$\text{?} \text{indicates text missing or illegible when filed}$$

Equations (13)-(16) contains terms to represent the generation and dissipation of the turbulence scalars which can be obtained based on well-established empirical correlations fitted to experimental data. The correlations are not listed here to keep the section concise. Please refer to Wei et al. (Conjugate heat transfer and fluid flow modeling for liquid microjet impingement cooling with alternating feeding and draining channels, Fluids. 4 (2019), the content of which is incorporated by reference herein in its entirety) for the complete turbulence model with correlations.

The above governing equations are subjected to the following boundary conditions:

### 1. Heat Flux Conditions at the Bottom of Individual Chip Region:

$$- {k}_{f} \frac{\partial T}{\partial n} = {q}^{″} ; {q}^{″} = \{ \begin{matrix}{q}_{l}^{″} & for Logic chip \\ {q}_{HBM - i}^{″} & for {i}^{th} HBM chip\end{matrix} \qquad ( 17 )$$

### 2. Inlet Conditions at Cooler Inlet:

$$Φ = \{ \begin{matrix}0 & T \leq {T}_{pc , l} \\ \frac{T - {T}_{pc , l}}{{T}_{pc , u} - {T}_{pc , l}} & {T}_{pc , l} < T \leq {T}_{pc , u} \\ 1 & T > {T}_{pc , u}\end{matrix} \qquad ( 18 )$$

### 3. Outlet Conditions at Cooler Outlet:

$${P}_{out} = 0 Pa \qquad ( 19 )$$

### 4. Adiabatic Conditions at Remaining Walls:

$$\frac{\partial T}{\partial n} = 0 \qquad ( 20 )$$

The first boundary condition is applied using a shell conduction model which can account for the conjugate heat transfer at solid-liquid interface without the need of explicitly modelling the solid. A shell thickness of Lₛₕ=0.35 cm (physical distance of surface from the first layer of thermocouples in copper block) is used with oxygen free copper being the wall material. This will enable stable convergence and more realistic prediction of temperature gradient over the heat dissipating surface. The aforementioned governing equations (10)-(16) are subjected to the above mentioned boundary conditions (17)-(20) and are solved using ANSYS Fluent 2023R2 available at Purdue University, West Lafayette. Fluent is a CFD software employing finite volume formulation to numerically solve the governing equations. Pressure based solver is used with double precision. Semi-Implicit Method for Pressure Linked Equations (SIMPLE) is used for pressure velocity coupling. Pressure Staggering Option (PRESTO!) is used to interpolate pressure at element faces while momentum equations are discretized using Quadratic Upwind Interpolation scheme for Convective Kinetics (QUICK). The energy equation and the turbulence transport equations are solved using second order upwind schemes. The under-relaxation factors for pressure, momentum, energy and turbulence scalars were set to 0.85, 0.8, 1, 0.8. Convergence is said to be achieved when the residuals for continuity, momentum, energy and turbulence equations falls below 10-4, 10-5, 10-8 and 10-4 respectively.

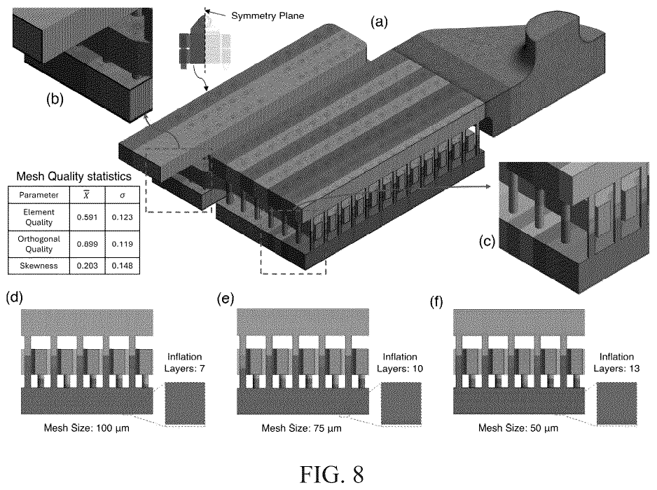

To obtain accurate numerical solution at optimum computational expense, a mesh sensitivity study is carried out at mesh sizes of 100 um, 75 um and 50 um. FIG. 8 panel A shows the overall mesh used for the numerical study. The entire computational domain encloses a total fluid volume of 7747.24 mm³ and hence special efforts have been made to minimize the computational time in terms of minimizing overall mesh elements and optimizing the mesh quality parameters. The entire domain is segregated into smaller blocks to exert better mesh control and generate prismatic elements with high orthogonality and minimal skewness. FIG. 8 panels B-C show the magnified views of mesh elements for HBMs and logic chip respectively. The dark concentrated region along the different walls highlights the inflation layers used at walls. Transition SST model requires sufficiently fine inflation layers such that y⁺<1 condition at the wall. Hence, the height of the first inflation layer is adjusted and the value of y⁺ for different surfaces is monitored during simulations to ensure this criteria is satisfied. FIG. 8 panels D-F show the mesh over the symmetry plane for the three different mesh sizes.

Magnified view of the individual inflation layers are also shown in subset images for each different mesh configurations. For a mesh size of 75 um, the fluid domain consists of 11.9 million cells and the mesh quality statistics are also tabulated and shown in FIG. 8 panels A-F. Segregating the entire domain into smaller blocks enables exertion of greater control over each region and helps in maximizing the orthogonal quality and minimizing element skewness. The average mesh orthogonal quality is ~0.9 (with a standard deviation of ~0.12) while the average skewness is ~0.2 (with a standard deviation of ~0.15). The complete mesh information for different mesh sizes along with mesh sensitivity results are discussed below: Mesh Details and sensitivity study.

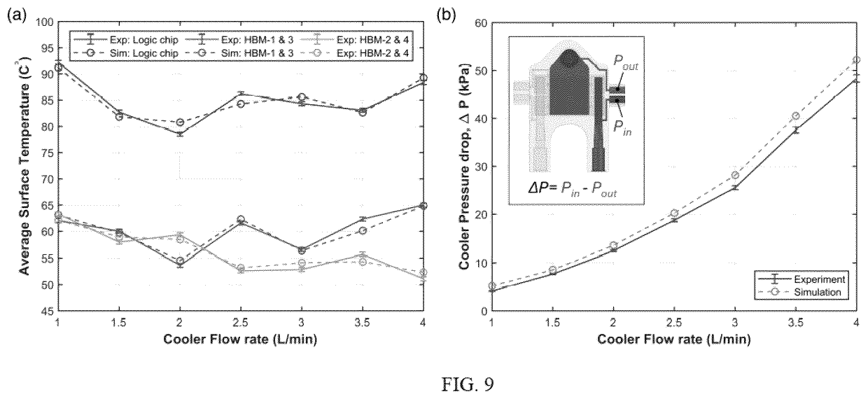

FIG. 9 panel A shows the comparison the numerical results for average chip surface temperature of logic chip and the four HBMs with the experimental results at maximum heat flux for each flow rate considered in the present study. It is observed that the numerical model has considerable accuracy and can accurately predict the average chip surface temperature of all five chips. The maximum deviation of numerical results is 2.89% for the average chip surface temperature of logic chip at a cooler flow rate of 2 L/min. As heat flux values extracted from the experiments are used for the validation of numerical model, the maximum deviation can be attributed to the uncertainty in calculation of heat flux and is well within acceptable range. FIG. 9 panel B shows the comparison of the experimental and numerical results for the overall cooler pressure drop at different flow rates. It can be inferred that the numerical model can make reasonably accurate prediction of the cooler pressure drop with the maximum deviation being 8.1% at the maximum flow rate. Thus, the numerical model can predict the flow field and temperature field within the cooler and the numerical results are used at appropriate instances to better elaborate and highlight the underlying system behaviour observed in the experimental results.

### Average Chip Surface Temperature

The present study aims to investigate the thermo-hydraulic performance of a microscale jet impingement cooler for a HPC heater setup and upgrade its TDP beyond 1 kW. The discussion first focusses on the surface temperature of different chips under a wide range of operating conditions and then proceeds to elucidate thermal resistance for different chips and the overall cooler pressure drop. Then the effect of logic chip power and cooler flow rate on surface temperature uniformity is comprehensively discussed. The last subsection then compares the series and parallel cooler designs in terms of various parameters and elaborates on the relative advantages of both designs.

The primary objective of a cooling solution is to minimize the chip temperature and ensure that it is below the maximum allowable limit. This minimizes thermal stresses within the package and ensures its reliability throughout its operating life. The HPC heater arrangement under consideration has multiple chips from which the logic chip has the maximum power dissipation while the surrounding HBMs have much smaller power dissipation but more stringent temperature constraint.

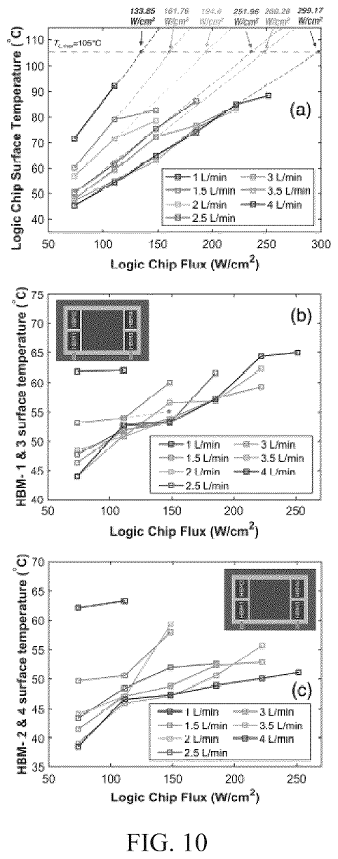

Thus, the effect of logic chip flux on the average surface temperature for all different chips is first investigated for cooler flow rate range of Q⋅_{flow}=1−4 L/min as shown in FIG. 10 panel A for logic chip. For a particular logic flux, increasing the cooler flow rate, increases the amount of fluid impinging over the logic chip which enhances the heat transfer and hence reduces the surface temperature of logic chip. The maximum reduction in the temperature is 36.6% as the cooler flow rate is increased from 1 L/min to 4 L/min at a logic flux of q′_{L}=73.96 W/cm² (PL=500 W). The plots of temperature at different flow rates come closer to each other as the latter increases and eventually collapse into each other beyond 3.5 L/min which highlights the saturation in heat transfer performance. Beyond this flow rate, the enhancement in heat transfer may not be significant. However, increasing the flow rate can minimize the temperature rise of the fluid across the HBMs which is the inlet temperature for logic chip nozzles. Hence, increasing the flow rate can enable upgrading the logic chip flux and the TDP of the HPC albeit at the cost of an increase the pressure drop.

For all different flow rates, the temperature of logic chip at respective maximum fluxes is well below the maximum allowable temperature of T_{L,max}=105° C. Instead, the maximum flux was dictated by the maximum temperature limit in the system, fixed at 300° C. throughout the experiments. The maximum flux, not subjected to this practical consideration can be obtained through linear extrapolation as shown in FIG. 10 panel A by the dotted lines. This approach is valid as the temperature rise is proportional to the increase in logic chip flux, indicated by the linearity of the curve. This linear nature of surface temperature plot with respect to chip power or flux is a well-established observation in single chip jet impingement cooling. However, these extrapolated values signify the single chip values and its realization for multi-chip packages depends on how the surrounding chiplets are affected at such high fluxes. Heat generated in logic chip may have alternative thermal paths apart from the jet impingement cooling over its own surface. These alternate paths are through the surroundings chips which are also cooled by jet impingement. Thus a portion of logic chip power may be dissipated through these alternative paths. This can lead to a logic temperature rise which falls short of the extrapolated value. This is observed in the experimental results of logic temperature for certain flow rates at their respective maximum heat fluxes.

The effect of logic chip flux on the average chip surface temperature for HBM 1 & 3 at different flow rates is shown in FIG. 10 panel B and for HBM 2 & 4, it is shown in FIG. 10 panel C at a HBM power of P_{HBM}=40 W, which was the maximum achievable power for the HBM heaters during experiments. The results were reported at the maximum HBM power to test the capability of the microscale jet impingement under stringent operating conditions. It is observed that the any change in logic flux also affects the temperature of HBMs even though their own power dissipation remains constant. The temperature of HBM 1 & 3 is observed to increase in approximately linear fashion across different flow rates as logic flux is increased. Similarly, the temperature of HBM 2 & 4 increases but in different manner, depending on the cooler flow rate. For high flow rates (Q⋅_{flow}>2 L/min), the temperature rise dampens or increases linearly as logic flux increases but at smaller flow rates, the temperature rise becomes disproportionately high. For example, at a cooler flow rate of 1.5 L/min, the temperature of HBM 1 & 3 increases by ΔT_{HBM},1-3~6° C. as logic flux is increased to q″_{L}=147.92 W/cm², while for HBM 2 & 4 the temperature rise under the same change in logic flux is ΔTHBM,2-4~8° C. This is opposite to the deviation in temperature rise of logic chip at the same heat flux, as discussed in previous paragraph. Just as the temperature rise of logic chip was smaller than the extrapolated value, the temperature rise of HBM is greater. As this effect is not observed as flow rate is increased, a rationale behind this may be that the heat transfer over HBM surfaces may not be sufficient to counter the heat gain from logic chip, thus resulting in a sudden increase in temperature. Whereas at high flow rates, the heat gain can be easily accommodated resulting in approximately linear manner for HBM 1 & 3. For HBM 2 & 4, as the flow rate is increased, the slope of temperature curves becomes smaller. This can indicate that heat transfer keeps on improving for HBM 2 & 4, while for HBM 1 & 3, it eventually becomes constant. This may depend on the distribution of incoming fluid into the inlet nozzles of HBMs and is further elucidated in next section. The present section solely focused on the temperature of the different chips of an HPC package and investigate the capability of the jet impingement cooling to meet the stringent temperature limits of logic chip and HBM for a wide range of operating conditions. The temperatures of logic chip and the HBMs under the maximum TDP of 1.86 kW (q″_{L,max}=251.48 W/cm² or P_{L}=1700 W) are T_{L}=88.37° C., T_{HBM,1-3}=64.38° C. and T_{HBM,2-4}=51.1° C., respectively, all of which are well within their respective temperature limits.

### Thermal Resistance

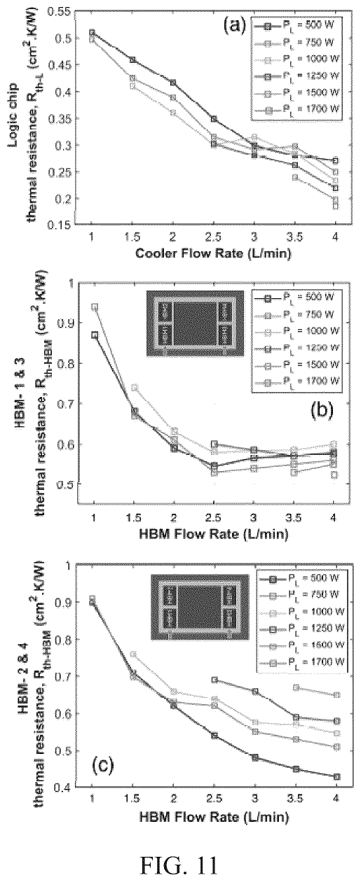

The variation of average thermal resistance for logic chip at different cooler flow rates is shown in FIG. 11 panel A. An increase in cooler flow rate for any given logic chip power reduces the thermal resistance as heat transfer rate is enhanced. However, as logic chip power is increased at a given flow rate, the thermal resistance decreases. Thermal resistance for jet impingement cooling of a single chip is independent of the heat flux and depends solely on the flow rate. However, for a multi-chip setup, the thermal resistance curve for different logic chip powers do not collapse into a single curve. Instead, distinct curves are observed for each logic chip power. The thermal resistance is essentially the ratio of temperature rise of a surface and the heat flux causing the temperature rise. For a single chip system, any increase in chip heat flux at a particular flow rate results in a proportionate increase in the temperature rise of the chip surface. Thus, thermal resistance for a single chip package, remains relatively constant with change in heat flux values and any deviation comes in terms of change in heat loss in the heater setup which is usually marginal for properly isolated enclosure. However, for the present multi-chip system, the surrounding chips provide alternate thermal paths and hence the heat transfer from logic chip to HBMs can be more significant. Hence the thermal resistance also varies based on logic power loss to the neighbouring copper blocks (through top plate material). The lowest thermal resistance of R_{th,L-min}=0.183 cm²·K/W is obtained at Q⋅_{flow}=4 L/min at P_{L}=1700 W. This also explains how the temperature rise of logic chip falls short of its extrapolated value depending on the logic chip power as discussed in previous section.

The thermal resistance for HBM 1 & 3 is shown in FIG. 11 panel B, and for HBM 2 & 4, it is shown in FIG. 11 panel C for different HBM flow rates. The thermal resistance for all HBMs decreases as HBM flow rate is increased. Further, the reduction in thermal resistance also reduces by increasing the HBM flow rate, indicating that the thermal resistance eventually becomes constant. This is a typical characteristic of jet impingement cooling, where beyond a certain flow rate, enhancement in heat transfer is not significant, and further increase in flow rate may not be justified. However, the thermal resistance of HBM 1 & 3 reaches its minima at Q⋅_{flow}~2.5 L/min beyond which, it becomes approximately constant. The saturation in heat transfer can be attributed to the lateral inlets of the cooler. The incoming flow through each inlet, gets distributed into two distinct streams, each of which enters the inlet nozzles of the front and back HBMs. At lower flow rates, the distribution is relatively equal.

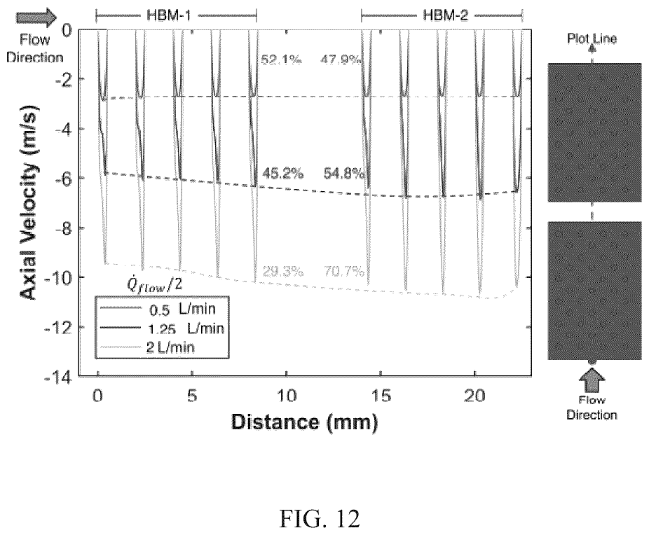

However, at higher flow rates, the fluid inertia becomes significant. As a result, the inlet nozzles of front HBMs gets a smaller portion of the incoming flow and the distribution becomes more disproportionate. FIG. 12 shows the numerical results of exit axial velocity profile through the inlet nozzles of HBM 1 and HBM 2 along with the flow distribution at different flow rates is also shown. The axial velocity increases with an increase in flow rate. The distribution at maximum flow rate is approximately in the ratio of 3:7, favouring the HBM-2 (back HBMs). Thus, even after increasing the cooler flow rate beyond Q⋅_{flow}~2.5 L/min, the flow rate for HBMs in the front doesn't increase substantially and its thermal resistance becomes relatively constant. On the other hand, the flow rate for back HBMs increase and its thermal resistance reduces. Hence, a constant thermal resistance over HBM 1 & 3 leads to a temperature rise which is approximately linear with respect to changes in logic flux. While for HBM 2 & 4, the thermal resistance further reduces and hence the slope of temperature plots becomes flatter, as discussed in previous section.

### Cooler Pressure Drop and Coefficient of Performance (COP)

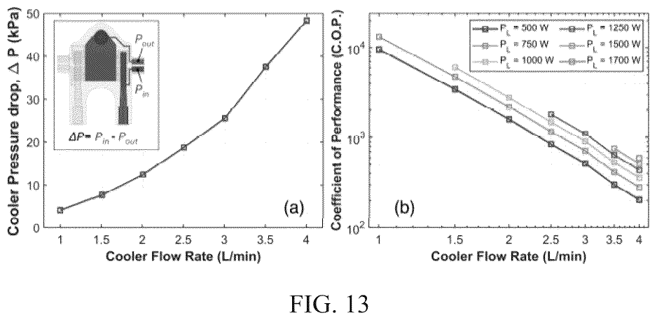

The variation of cooler pressure drop with the flow rate is shown in FIG. 13 panel A. As the cooler operates at larger flow rate, the pressure drop increases also increases significantly with nearly a twelvefold increase in pressure drop from ΔP=4.15 kPa at 1 L/min to ΔP=48.32 kPa at 4 L/min. Thus, by increasing the cooler flow rate to higher values, the enhancement in thermal performance decreases while the penalty in terms of pressure drop and pump power increases and a trade-off exists between the thermal performance and pressure drop. Coefficient of Performance (COP), defined as ratio of package TDP and pump power, can be useful parameter to evaluate the amount of TDP dissipated per unit penalty incurred in the form of pump power. The effect of cooler flow rate on the COP of thermal solution is shown in FIG. 13 panel B) For a given value of logic chip power (and TDP), the COP rapidly decreases as the cooler flow rate is increased as the pump power increases while the TDP remains constant. For a given cooler flow rate, increasing TDP increases the COP as more power FIG. 12 Numerical results of exit axial velocity profile through inlet nozzles of HBM 1 and 2 at different HBM flow rates. The relative distribution of flow rate is shown along with the trendline of velocity front. can be dissipated for the same amount of pump power. The maximum COP recorded was 13,156 for P_{L}=750 W at Q⋅_{flow}=1 L/min, while the COP at the maximum TDP of 1.86 kW was 577. Thus, to operate at optimum conditions, the cooler flow rate can be minimized such that thermal performance is sufficient to meet the temperature requirement. Apart from the surface temperature and cooler pressure drop, temperature gradient is another important parameter. Adverse temperature gradient can lead to thermal stresses and can compromise the reliability of the HPC package. Hence, next section focusses on the effect of logic chip power and cooler flow rate on the surface temperature uniformity for the five chips.

### Effect of Logic Chip Power and Cooler Flow Rate on Surface Temperature Uniformity

For jet impingement, the heat transfer rate is maximum on the chip surface directly below the inlet nozzles and deteriorates in radial direction as fluid goes towards the outlet. With distributed inlet-outlet configuration, each inlet is surrounded by four outlets and vice-versa. With fine nozzle pitch, these nozzles are closely packed and thus the radial distance between inlet and outlet is reduced. Thus, the non-uniformity in heat transfer rate may persist, albeit over much smaller length. With appropriately designed inlet plenum which can minimize flow maldistributions for inlet nozzles, local heat transfer behaviour of a unit cell (a set of inlet nozzle and the four surrounding outlet nozzles) can be repeated over a large chip area resulting in similar heat transfer across the chip surface. Hence, the surface temperature non-uniformity investigated for the proposed microscale jet impingement cooling is the variation of surface temperature in different unit cells and the reproducibility of a unit cell across the chip instead of the inherent non-uniformity within the unit cell which is usually concentrated in much smaller regions.

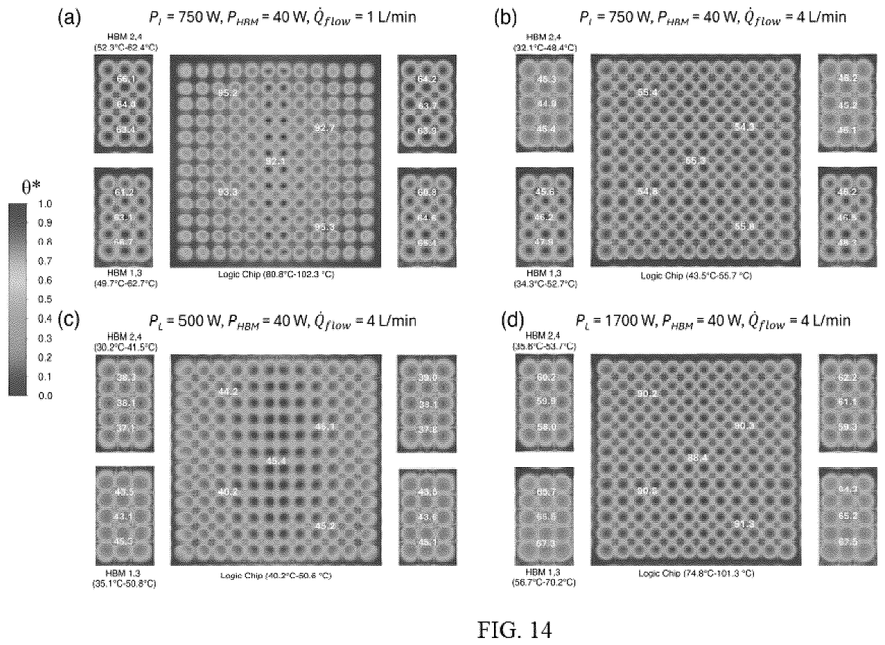

Non-dimensional temperature contours for each chip are used to compare the non-uniformity of surface temperature. The experimental results for surface temperature are also shown in white font at their respective locations on the package. The non-dimensional surface temperature contours for Q⋅_{flow}=I and 4 L/min at P_{L}=750 W and P_{HBM}=40 W (TDP=910 W) are shown in FIG. 14 panels A-B respectively. The maximum and minimum temperature for all chips is listed as ordered pairs next to the contour plots. The circular deep-blue coloured zones are the regions with maximum heat transfer rate and the minimum surface temperature and are positioned directly below the inlet nozzles. Similarly, the region between these circular deep-blue zones are directly below the outlet nozzles. The experimental results for the logic chip at Q⋅_{flow}=1 L/min is within 3.1° C. which then reduces to 1.5° C. as the flow rate is increased to Q⋅_{flow}=4 L/min. Qualitatively comparing the contour maps for the two cases, reveals that increasing the flow rate also reduces the concentration of red coloured zones while that of the high heat transfer rate zones (deep-blue coloured) increases, highlighting the enhancement in heat transfer and uniformity. FIG. 14 panels C-D show the contours of non-dimensional temperature at P_{L}=500 W (TDP=660 W) and P_{L}=1700 W (MP=1.86 kW) at P_{HBM}=40 W and Q⋅_{flow}=4 L/min. The experimental results for logic chip temperature at PL=500 W are within 2° C. while the results at P_{L}=1700 W are within 2.9° C. Comparison of contours shows the temperature gradient increases with the logic chip power, as the areas of high and low heat transfer becomes more distinct at P_{L}=1700 W, as compared to the comparatively diffused contour for P_{L}=500 W. Additionally the experimental results for all HBMs under different flow rate and logic chip power conditions also have excellent temperature uniformity and all values fall within 5.5° C. of each other. Thus, the microscale jet impingement can provide considerable surface temperature uniformity for a wide range of operating conditions.

### Comparison Between Series and Parallel Cooler

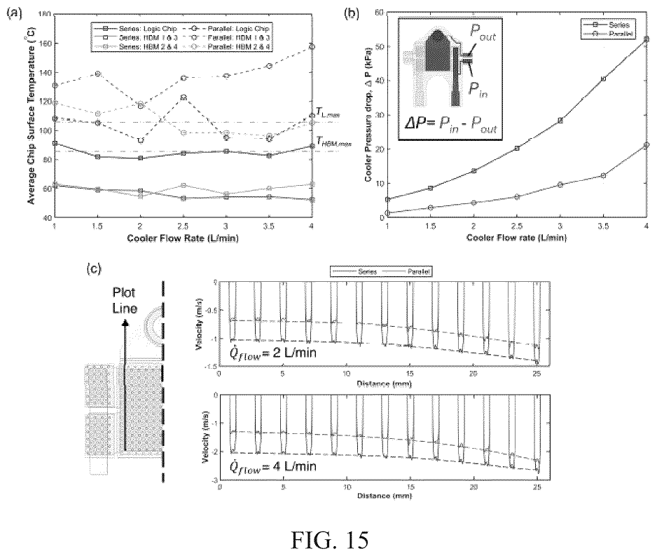

This section discusses the key differences between series and parallel configuration of multichip jet impingement cooler. All the results discussed in this section are numerical results obtained from solving the numerical model, which was comprehensively discussed above. FIG. 15 panel A shows the average chip surface temperature for logic chip and the HBMs at different cooler flow rates for series and parallel configuration. Maximum heat fluxes for each chip at different flow rates, obtained from experiments, were used for comparison. The series cooler maintains the average surface temperature of logic chip below the maximum temperature limit of T_{L,max}=105° C., while the parallel cooler fails to do so at several flow rates with the maximum average surface temperature being T_{L,max}=122° C. for q″_{L}=147.93 W/cm². Further, the average surface temperature of the logic chip is at least 10° C. lower for the series as compared to the parallel configuration for any given flow rate. Similarly, the average surface temperature of HBMs is well below the maximum temperature limit of T_{L,max}=85° C. for series configuration. While for the parallel counterpart, maximum temperature constraint was not met for HBM 1 & 3, while it was met for HBM 2 & 4 only after increasing the cooler flow rate beyond Q⋅_{flow}=2 L/min. A key issue with parallel design is that the distribution of flow into inlet nozzles of different chips is influenced solely by the cooler flow rate. At lower flow rates, nozzles near the inlet get a significant of the incoming flow while at higher flow rate, these nozzles get smaller amount of the flow rate. This is due to the inertia of the incoming flow as discussed for HBM inlets nozzles in earlier sections.

FIG. 15 panel C shows the exit velocity profile for series and parallel coolers for the first row of inlet nozzles at different flow rates. The trendlines in the plot shows that the flow through the inlet nozzles non-uniform for the parallel design. Further, this non-uniformity increases with the cooler flow rate. The flow for the inlet nozzles in series configuration is also non-uniform. However, as the inlet flow for series design flows towards logic from the opposite sides, the flow travels half the length of logic chip. Whereas for parallel design, the flow travels the entire logic chip length. Hence the non-uniformity in series design is small as compared to the parallel counterpart. Further, for series configuration, the entire cooler flow rate enters the inlet nozzles of logic chip, while for parallel design, it gets distributed. Hence, the average velocity through inlet nozzles is much higher in series design which dampens the effect of velocity nonuniformities on surface temperature. The only disadvantage with series configuration is the larger cooler pressure drop as compared to parallel design as the overall flow length is greater as shown in FIG. 15 panel B. Further, the entire fluid volume flows through this length resulting in much higher pressure drop. The maximum difference in pressure drop is ~32 kPa.

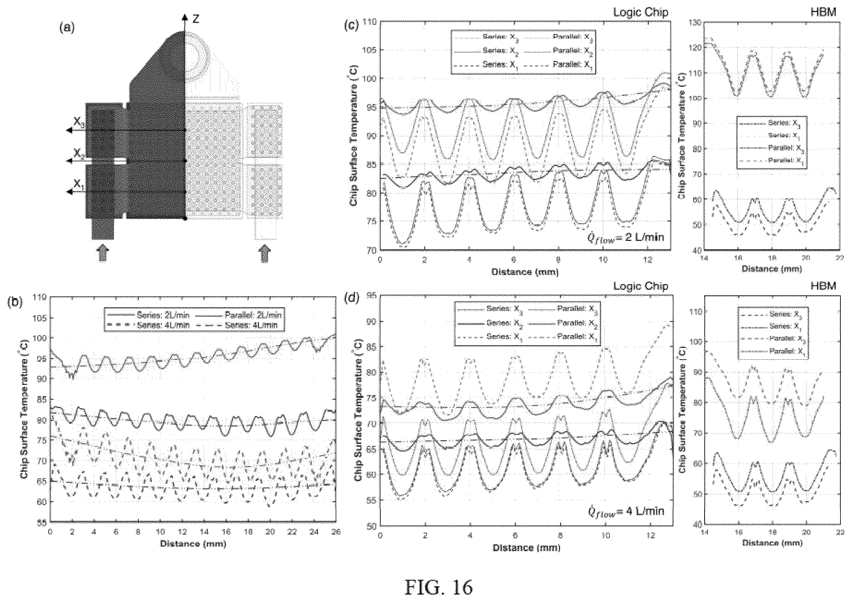

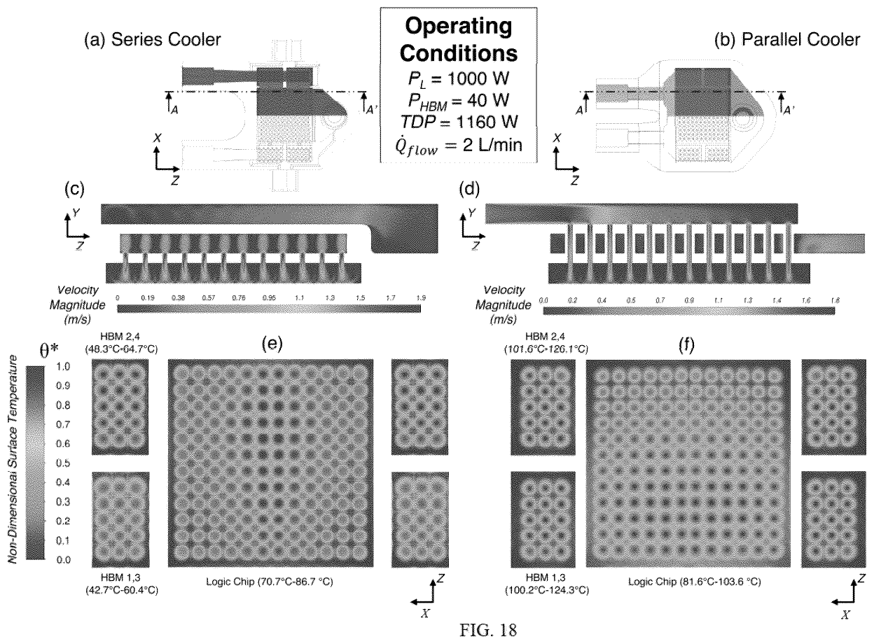

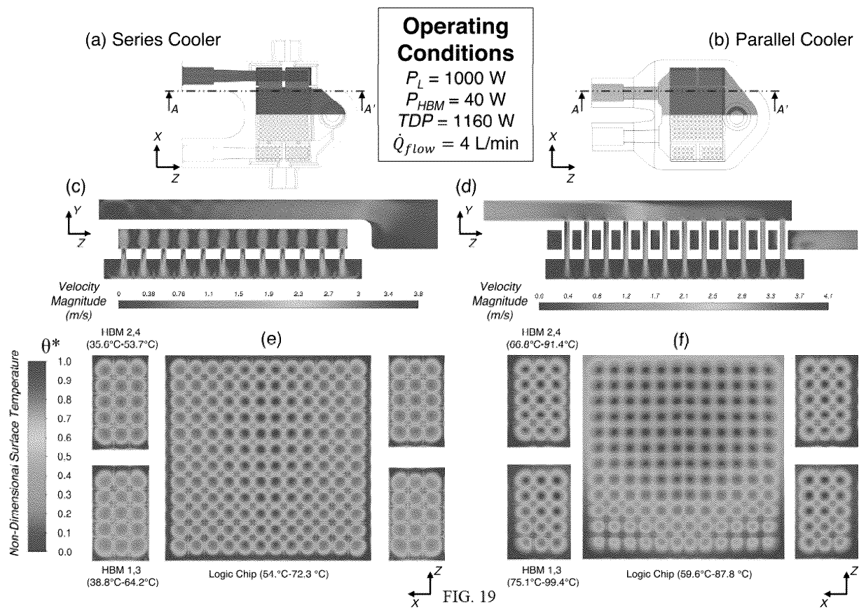

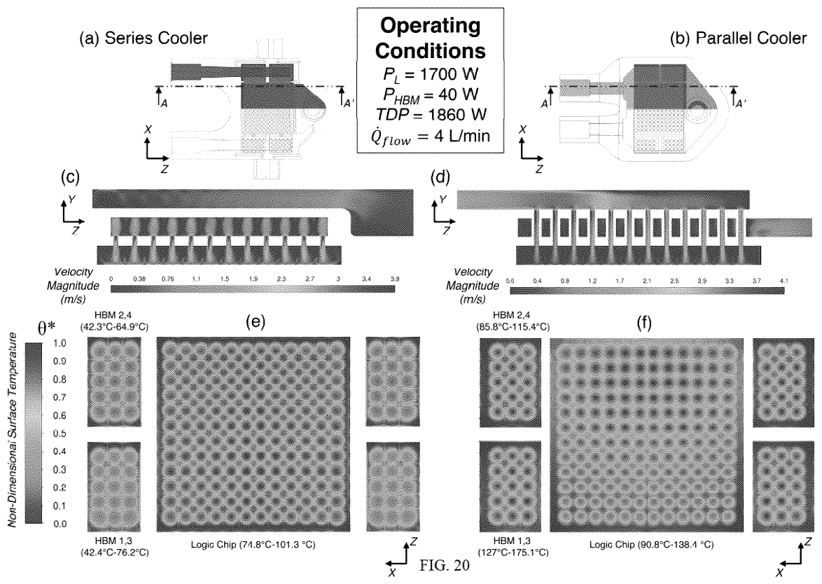

FIG. 16 panels A-C show the variation of surface temperature of logic chip and HBMs along different plot lines shown FIG. 16 panel A. Separate schematic for parallel cooler is not shown here as the data is exported along the same lines shown in FIG. 16 panels A-B show the variation of surface temperature for logic chip along plot line Z at Q⋅_{flow}=2 and 4 L/min. At Q⋅_{flow}=2 L/min, the temperature for parallel cooler progressively increases from 93° C. to 100° C. as indicated by the trendline, where for series cooler, it marginally reduces from 81° C. to 80° C. Increasing the flow rate to Q⋅_{flow}=4 L/min, reduces the temperature for both coolers. However, the trend of surface temperature changes for parallel cooler as the indicated by the trendline. It first reduces and reaches a minima after which it marginally increases. This observation is in excellent agreement with the argument presented in previous paragraph that the fluid inertia at higher flow rate causes the initial rows of nozzles to receive smaller amount of flow while the middle nozzles get the maximum portion of the incoming flow. Hence, the temperature also reaches a minima at the location with maximum flow. The temperature variation for series cooler at Q⋅_{flow}=4 L/min is within 1° C. as indicated by the trendline. The cyclic nature of the temperature variation is a consequence of the distributed inlet-outlets used for the cooler nozzles. Hence the temperature is minimum in the vicinity of nozzles and maximum in the vicinity of outlet nozzles. The temperature variation along plot lines X₁, X₂ and X₃ is shown in FIG. 16 panel C for Q⋅_{flow}=2 L/min and in FIG. 16(d) for Q⋅_{flow}=4 L/min. It can be observed that the temperature variation along plot line X₁ and X₃ is more prominent as these plot line pass through the inlet nozzle positions while variation along X₂ is less prominent. For series cooler, the temperature variation along plot lines X₁ and X₃ is similar irrespective of the cooler flow rate. But for parallel cooler, the temperature variation along both lines is different and the gap further widens as the cooler flow rate is increased. The temperature variation for series cooler is within 2° C. for Q⋅_{flow}=2 and 4 L/min along X₂ plot line while the same for parallel cooler is within 3° C. and 4° C. for Q⋅_{flow}=2 and 4 L/min respectively. Thus, it can be concluded that the surface temperature uniformity for microscale jet impingement cooling of a multi-chip HPC package is excellent with series cooler having superior performance as compared to the parallel cooler. Further information on surface temperature uniformity in terms of contour plots of nondimensional surface temperature for the series and parallel cooler is FIG. 18 panels A-F, FIG. 19 panels A-F, and FIG. 20 panels A-F.

### CONCLUSION

The present study is the first reported experimental implementation of microscale jet impingement cooling for an HPC package with 1.86 kW of thermal design power. The proposed cooling solution tackled the challenge of upgrading the TDP of multi-chip packages for HPC systems while simultaneously meeting the temperature constraints of all individual chips for a wide range of operating conditions. The package with a central logic chip and four HBMs, surrounding the logic chip on opposite sides, was realised using a copper block heater setup while the cooler was fabricated from high temperature resin using stereolithography. The temperature constraint for the logic chip was 105° C. while for HBMs, it was 85° C. The thermal performance of the proposed cooling solution is investigated experimentally in terms of the surface temperature of different chips, their thermal resistance and the surface temperature uniformity for a range of cooler flow rates and package TDP. The pressure drop and COP of the cooler is also investigated for a range of cooler flow rates. Numerical results are also used at appropriate instances to elaborate on the underlying fluid flow field and its effect on the heat transfer. Lastly, a brief comparison between the proposed series cooler and the parallel cooler is discussed to highlight the relative advantages of both configurations. Certain nonlimiting important are as listed below:
1. Logic chip heat flux was the dominant parameter affecting the average chip temperature of logic chip itself and the surrounding HEM chips. At Q⋅_{flow}=4 L/min, increasing the logic chip flux from q″_{L}=73.96 W/cm² (P_{L}=500 W) to 251.48 W/cm² (P_{L}=1700 W) increased the average surface temperature of logic chip from TL=45.34° C. to T_{L}=88.37° C. (~95% increase). For the same increase in logic chip flux, the temperature of HBM 1 & 3 increases from T_{HBM,1-3}=44.0° C. to 61.3° C. (28.2% increase) while that of HBM 2 & 4 increases from T_{HBM,2-4}=38.58° C. to 51.1° C. (32.5% increase), despite keeping the power dissipation for HBMs constant at P_{HBM}=40 W.
2. The increase in the surface temperature of HBMs, as a result of increasing logic chip flux, can be attributed to the thermal coupling which is essentially conduction between the different chips. Thus, apart from self-heating, thermal coupling is another the key factor limiting the maximum TDP of the package, as power dissipation of a particular chip can void temperature limit of other chips.
3. Increasing logic chip flux at constant flow rate, resulted in a non-linear rise in the logic chip temperature. This was a noticeable deviation from the expected linear temperature rise for logic chip. This was because increasing the logic chip flux also increased the power conducted from logic chip to the surrounding HBMs through thermal coupling. Thus, similar but opposite effect was observed for temperature of HBMs which also experienced a non-linear temperature rise.
4. The non-linear temperature rise is also a function of the cooler flow rate which influences the heat transfer rate over logic chip. At higher flow rates and, the corresponding heat transfer rate is also high and thus power loss from logic chip to surrounding chips is and the deviation (temperature difference between actual results and linear temperature rise predictions) is small. For example, deviation at q″_{L}=147.93 W/cm² is ~18° C. for Q⋅_{flow}=2 L/min and ~9° C. for Q⋅_{flow}=2.5 L/min. Increasing flow rates beyond Q⋅_{flow}=3 L/min at the same logic power, this deviation becomes negligible.
5. The thermal resistance for all chips reduces by increasing the cooler flow rate, with minimum thermal resistance recorded for logic chip being R_{th,L-min}=0.183 cm²·K/W is obtained at Q⋅_{flow}=4 L/min at q″_{L}=251.48 W/cm² (P_{L}=1700 W) while the same for HBMs were R_{th,HBM-1,3}=0.52 cm²·K/W and R_{th,HBM-2,4}=0.42 cm²·K/W.
6. The cooler pressure drop increases from ΔP=4.15 kPa at Q⋅_{flow}=1 L/min to ΔP=48.32 kPa at Q⋅_{flow}=4 L/min while the corresponding COP reduces from 13,156 to 283 for a TDP of 910 W. The COP at the maximum TDP of 1.86 kW was estimated to be 577.
7. The surface temperature uniformity improved with an increase in the cooler flow rate while increasing logic chip flux marginally reduced the temperature uniformity. Even at the highest logic chip heat flux (and highest TDP), the measurements for logic chip surface temperature were within 2.9° C. of each other. The contours maps of non-dimensional temperature highlighted that heat transfer within a unit cell was reproduced throughout the chip even at the highest heat flux. This highlights the excellent capability of microscale jet impingement cooling with distributed inlet-outlets in maintaining uniform heat transfer over the surface of a logic chip as large as 676 mm².
8. Comparison of series and parallel designs indicated the series design was able to simultaneously meet the temperature constraints of all chips for a logic chip flux range of q″_{L}=73.96-251.48 W/cm² while parallel design failed to do so. However, the pressure drop penalty to achieve better heat transfer in series design is also greater as compared to parallel design, with maximum difference in pressure drop being ~32 kPa.
9. Investigating the temperature variation across different plot lines over the logic chip and HEM surface indicating that the temperature variation was within 3° C. over the chip surface for series cooler. Further, the effect of non-uniformity due to lateral inlets was negligible for series cooler while it was more prominent in parallel cooler and increased further with an increase in the cooler flow rate.

### INCORPORATION BY REFERENCE

References and citations to other documents, such as patents, patent applications, patent publications, journals, books, papers, web contents, have been made throughout this disclosure, including to the Supplementary. The Supplementary, and all other such documents are hereby incorporated herein by reference in their entirety for all purposes.

### EQUIVALENTS

The invention may be embodied in other specific forms without departing from the spirit or essential characteristics thereof. The foregoing embodiments are therefore to be considered in all respects illustrative rather than limiting on the invention described herein.

### EXAMPLES

### Example 1: Mesh Details and Sensitivity Study

To ensure that the results of numerical model are independent of the mesh used, a mesh sensitivity study was carried out and this appendix discusses its results and tabulates the mesh settings for each case. The Table A.1 lists the details of the mesh settings used in ANSYS FLUENT 2023R2, available at Purdue University, to solve the numerical model:

TABLE A.1
Mesh settings used for spatial discretization
of the computational domain

Mesh settings

| Mesh Parameter | Coarse | Medium | Fine |
|---|---|---|---|
| Sizing proximity function | OFF | | |
| Sizing curvature function | ON | | |
| Mesh Defeaturing | ON | | |
| Defeaturing size | 1 × 10⁻³ mm | | |
| Curvature minimum size | 2 × 10⁻³ mm | | |
| Element smoothing | High | | |
| Element size | 100 μm | 75 μm | 50 μm |
| Inflation | Program controlled | | |
| Inflation option | Smooth Transition | | |
| No of inflation layers | 7 | 10 | 13 |
| Growth Rate | 1.1 | 1.1 | 1.1 |
| No of nodes | 6.52 | 10.56 | 24.54 |
| | million | million | million |
| No of elements | 7.21 | 11.94 | 22.11 |
| | million | million | million |
| Average mesh quality | 0.453 | 0.591 | 0.634 |
| Average mesh orthogonality | 0.721 | 0.899 | 0.902 |
| Average mesh skewness | 0.351 | 0.203 | 0.187 |

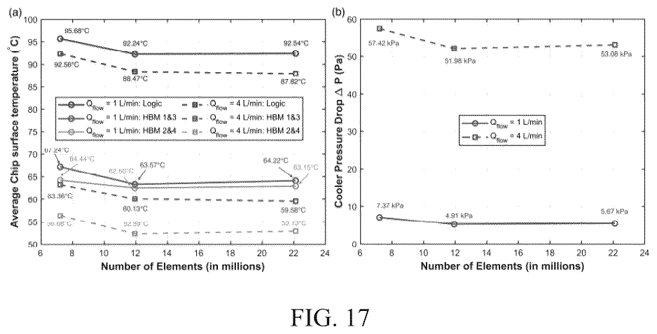

Simulations are run for all three mesh settings at the maximum and minimum flow rates to evaluate the results at the extremes considered in the present study. Further, heat flux evaluated from experimental measurements were used to investigate the mesh sensitivity. The results are shown in FIG. 17 panels A-B while the relative percentage change is tabulated in Table A.2.

TABLE A.2
Results of mesh sensitivy study at \dot{Q}_{flow} = 1 and 4 L/min

| Parameter | Mesh size | \dot{Q}_{flow} = 1 L/min | \dot{Q}_{flow} = 4 L/min |
|---|---|---|---|
| Logic chip | Coarse | 95.68 | 92.56 |
| Temperature | Medium | 92.24 (3.69% ↓) | 88.47 (4.42% ↓) |
| (° C.) | Fine | 92.54 (0.33% ↑) | 87.82 (0.74% ↓) |
| HBM 1 & 3 | Coarse | 67.24 | 63.36 |
| Temperature | Medium | 63.57 (5.46% ↓) | 60.13 (5.1% ↓) |
| (° C.) | Fine | 64.22 (1.02% ↑) | 59.58 (0.92% ↓) |
| HBM 2 & 4 | Coarse | 64.44 | 56.68 |
| Temperature | Medium | 62.50 (3.01% ↓) | 52.59 (7.21% ↓) |
| (° C.) | Fine | 63.15 (1.04% ↑) | 53.13 (1.03% ↑) |
| Cooler | Coarse | 7.37 | 57.42 |
| Pressure | Medium | 4.91 (33.37%↓) | 51.98 (9.47% ↓) |
| drop | Fine | 5.67 (15.48%↑) | 53.08 (2.12% ↑) |

As shown in above table, the average surface temperature for all chips, at both flow rates, reduces as mesh size is reduced from 100 um (coarse) to 75 um (medium) with the maximum reduction being 7.21% for HEM 2 & 4 at Q⋅_{flow}=4 L/min. Further reduction in mesh size from 75 um (medium) to 50 um (fine), marginally increases the average surface temperature for all chips with the relative changes being ~1% for all chips. Similarly, the relative change in pressure drop from medium to fine mesh is 15.48% and 2.12% for Q⋅_{flow}=1 and 4 L/min. However, the corresponding increase in number of elements from medium to fine is 10.17 millions (85.18% increase). Hence, further reduction in mesh size is not justified as the relative change in temperature and pressure drop results is marginal as compared to the increase in computational expense. Thus, the medium mesh settings are used for discretizing the computational domain and solve the numerical model for different operating conditions.

What is claimed is:

1. A high performance computing (HPC) system comprising:
a logic chip;
a plurality of high bandwidth memory (HBM) chips; and
a jet impingement cooling arrangement; wherein the HPC is arranged such that incoming fluid from the jet impingement cooling arrangement first impinges over the HBMs and is then redirected towards the logic chip to impinge again, thus cooling the HBMs and logic chip in series.

2. The HPC system of claim 1, wherein the jet impingement cooling arrangement had distributed inlet nozzles and outlet nozzles.

3. The HPC system of claim 2, wherein each inlet nozzle is surrounded by four outlet nozzles and vice-verse, except for the outermost master outlet nozzles.

4. The HPC system of claim 3, wherein each HBM chip had an inlet nozzle array of 3×5 at a pitch of 2 mm.

5. The HPC system of claim 4, wherein the logic chip had an inlet nozzle array of 12×12 at a pitch of 2 mm.

6. The HPC system of claim 2, wherein the jet impingement cooling arrangement has a total of 204 inlet nozzles spread over a total chip area of 1060 mm².

7. The HPC system of claim 2, wherein each inlet and outlet nozzle has a diameter of 500 micrometers.

8. The HPC system of claim 1, wherein the jet impingement cooling arrangement comprises two master inlet nozzles that split the overall flow rates into two inlet streams, and one common master outlet nozzle for both inlet streams.

9. The HPC system of claim 2, wherein the jet impingement cooling arrangement further comprises pressure tappings, which provide fluid pathways from inlet nozzles and outlet nozzles.

10. The HPC system of claim 9, wherein the fluid pathways are connected across a pressure transducer through tub and the overall pressure drop is measured, wherein thermocouple holes are also provided in the jet impingement cooling arrangement to measure temperature of the fluid after the fluid has impinged over the HBMs.

11. A method for cooling a high performance computing (HPC) system comprising:
providing an HPC having a logic chip; a plurality of high bandwidth memory (HBM) chips; and a jet impingement cooling arrangement; and
providing, via the jet impingement cooling arrangement, a flow of fluid to the HPC, wherein the HPC is arranged such that the incoming fluid from the jet impingement cooling arrangement first impinges over the HBMs and is then redirected towards the logic chip to impinge again, thus cooling the HBMs and logic chip in series.

12. The method of claim 11, wherein the jet impingement cooling arrangement had distributed inlet nozzles and outlet nozzles.

13. The method of claim 12, wherein each inlet nozzle is surrounded by four outlet nozzles and vice-verse, except for the outermost master outlet nozzles.

14. The method of claim 13, wherein each HBM chip had an inlet nozzle array of 3×5 at a pitch of 2 mm.

15. The method of claim 14, wherein the logic chip had an inlet nozzle array of 12×12 at a pitch of 2 mm.

16. The method of claim 12, wherein the jet impingement cooling arrangement has a total of 204 inlet nozzles spread over a total chip area of 1060 mm².

17. The method of claim 12, wherein each inlet and outlet nozzle has a diameter of 500 micrometers.

18. The method of claim 11, wherein the jet impingement cooling arrangement comprises two master inlet nozzles that split the overall flow rates into two inlet streams, and one common master outlet nozzle for both inlet streams.

19. The method of claim 12, wherein the jet impingement cooling arrangement further comprises pressure tappings, which provide fluid pathways from inlet nozzles and outlet nozzles.

20. The method of claim 19, wherein the fluid pathways are connected across a pressure transducer through tub and the overall pressure drop is measured, wherein thermocouple holes are also provided in the jet impingement cooling arrangement to measure temperature of the fluid after the fluid has impinged over the HBMs.
